(19) United States
(12) Patent Application Publication
(10) Pub. No.: US 2022/0012563 A1
(43) Pub. Date: Jan. 13, 2022

(54) METHODS AND APPARATUS FOR HIGH THROUGHPUT COMPRESSION OF NEURAL NETWORK WEIGHTS

(71) Applicants: Alejandro Castro Gonzalez, Chandler, AZ (US); Praveen Nair, Chandler, AZ (US); Somnath Paul, Hillsboro, OR (US); Sudheendra Kadri, Folsom, CA (US); Palanivel Guruvareddiar, Chandler, AZ (US); Aaron Gubrud, Tempe, AZ (US); Vinodh Gopal, Westborough, MA (US)

(72) Inventors: Alejandro Castro Gonzalez, Chandler, AZ (US); Praveen Nair, Chandler, AZ (US); Somnath Paul, Hillsboro, OR (US); Sudheendra Kadri, Folsom, CA (US); Palanivel Guruvareddiar, Chandler, AZ (US); Aaron Gubrud, Tempe, AZ (US); Vinodh Gopal, Westborough, MA (US)

(21) Appl. No.: 17/484,226

(22) Filed: Sep. 24, 2021

(51) Int. Cl. G06N 3/04

(52) U.S. Cl. CPC G06N 3/04

(57) ABSTRACT

Methods, apparatus, systems, and articles of manufacture are disclosed for high throughput compression of neural network weights. An example apparatus includes at least one memory, instructions in the apparatus and processor circuitry to execute the instructions to determine sizes of data lanes in a partition of neural network weights, determine a slice size based on a size difference between a first data lane and a second data lane of the data lanes in the partition, the first data lane including first data, the second data lane including second data, the second data of a smaller size than the first data, cut a portion of the first data from the first data lane based on the slice size, and append the portion of the first data to the second data lane.

### FIELD OF THE DISCLOSURE

This disclosure relates generally to neural networks and, more particularly, to methods and apparatus for high throughput compression of neural network weights.

### BACKGROUND

Neural networks process a variety of considerations when generating an inference. A size of a neural network increases with a quantity of the considerations and/or complexities in relationships between the considerations. Although more nodes and/or a complex network can improve an accuracy of the neural network, the increased size can make neural networks more difficult to store and utilize and, thus, limit the use cases thereof.

### BRIEF DESCRIPTION OF THE DRAWINGS

FIG. 1 illustrates an overview of an edge cloud configuration for edge computing.

FIG. 2 illustrates operational layers among endpoints, an edge cloud, and cloud computing environments.

FIG. 3 illustrates an example approach for networking and services in an edge computing system.

FIGS. 4A-B illustrate prior art processes of compressing neural network weights.

FIG. 5 is a block diagram of an example system that performs high throughput compression of neural network weights in accordance with teachings of this disclosure.

FIG. 6 is a block diagram of example weight compression circuitry of the system of FIG. 5.

FIG. 7 illustrates example partitions that neural network weights are split into by example quantization circuitry of the example weight compression circuitry of FIGS. 5 and/or 6.

FIG. 8 is a block diagram of example variable length coding circuitry of the example weight compression circuitry of FIGS. 5 and/or 6.

FIGS. 9A-B illustrate a first example of variable length encoding performed by the example variable length coding circuitry of FIGS. 6 and/or 8.

FIG. 10 illustrates a second example of variable length encoding performed by the example variable length coding circuitry of FIGS. 6 and/or 8.

FIG. 11 is a block diagram of an example edge device of the example system of FIG. 5.

FIG. 12 is a block diagram of example weight decompression circuitry of the edge device of FIGS. 5 and/or 11.

FIG. 13 illustrates an example process performed by the example weight decompression circuitry of FIGS. 11 and/or 12.

FIG. 14 illustrates an example compression and decompression process performed by the example system of FIG. 5.

FIG. 15 shows example graphs illustrating space savings that result from utilizing the example system of FIG. 5 relative to the prior art of FIG. 4.

FIG. 16 is a first flowchart representative of example machine readable instructions that may be executed by example processor circuitry to implement the example weight compression circuitry of FIGS. 5 and/or 6.

FIG. 17 is a second flowchart representative of example machine readable instructions that may be executed by example processor circuitry to implement the example weight compression circuitry of FIGS. 5 and/or 6.

FIG. 18 is a flowchart representative of example machine readable instructions that may be executed by example processor circuitry to implement the example edge device of FIGS. 5 and/or 11.

FIG. 19 is a first flowchart representative of example machine readable instructions that may be executed by example processor circuitry to implement the example weight decompression circuitry of FIG. 12.

FIG. 20 is a second flowchart representative of example machine readable instructions that may be executed by example processor circuitry to implement the example weight decompression circuitry of FIG. 12.

FIG. 21 is a block diagram of an example processing platform including processor circuitry structured to execute the example machine readable instructions of FIGS. 16 and/or 17 to implement the example weight compression circuitry of FIGS. 5 and/or 6.

FIG. 22 is a block diagram of an example processing platform including processor circuitry structured to execute the example machine readable instructions of FIGS. 18, 19, and/or 20 to implement the example edge device of FIGS. 5 and/or 11.

FIG. 23 is a block diagram of an example implementation of the processor circuitry of FIGS. 21 and 22.

FIG. 24 is a block diagram of another example implementation of the processor circuitry of FIGS. 21 and 22.

FIG. 25 is a block diagram of an example software distribution platform (e.g., one or more servers) to distribute software (e.g., software corresponding to the example machine readable instructions of FIGS. 16, 17, 18, 19, and/or 20) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name. As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

Approximating language, as used herein throughout the specification and claims, is applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value, or the precision of the methods or machines for constructing or manufacturing the components and/or systems. For example, the approximating language may refer to being within a ten percent margin.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmed with instructions to perform specific operations and including one or more semiconductor-based logic devices (e.g., electrical hardware implemented by one or more transistors). Examples of processor circuitry include programmed microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of the processing circuitry is/are best suited to execute the computing task(s).

### DETAILED DESCRIPTION

Neural networks (e.g., artificial neural networks, deep neural networks, etc.) are utilized for predictive modeling and/or adaptive control in a wide range of applications. For instance, a neural network can be trained via a dataset, which enables the neural network to determine a mathematical or computational model that performs an inference in response to an input. The training of the neural network develops weights representative of a strength of a connection between units (e.g., nodes). Complex neural networks account for a wide range of factors to develop a tailored inference based on the circumstances in any given application. That is, the neural network can utilize more nodes and/or intricate connections between the nodes to develop an inference that corresponds with the parameters of the situation. However, increased connections between nodes results in more weights and, in turn, more storage required to store the weights.

To decrease the amount of storage required for complex neural networks, techniques have been developed to sparsify the neural network weights without significantly impacting the accuracy of the network. For instance, the weights may encounter pruning, which removes weights below a certain threshold, and the network can be retrained to determine the removed weights based on weights that were not removed. Additionally, the weights may encounter quantization to reduce the number of bits required to store each weight. For instance, weights can be divided into partitions to reduce a size thereof.

In some instances, the pruned and quantized neural network weights undergo further compression via byte rotation before a compressed version of the weights is stored. Specifically, the weights may be spread unevenly across different data lanes in a partition in response to being quantized and, in turn, byte rotation systematically reassigns certain bits representative of the weight to certain data lanes. However, byte rotation can result in reduced compression (e.g., space savings) when data (e.g., bits) in one or more data lanes has a low correlation. Specifically, the byte rotation mixes the bits representative of the weight evenly across the different data lanes. Ideally, the mixed data lanes would have some correlation between the values of the bits and the respective location thereof in the data lanes (e.g., the last four bits of each data lane has the same value), in which case the correlated data can be compressed. However, the byte rotation may mix highly uncorrelated data to make the data lanes even, which reduces an overall compressibility of the data lanes. That is, the use of such byte rotation to make the distribution even between the data lanes may cause the bits in a data lane that originally had a high correlation to become separated and, in turn, reduce the overall compressibility of the data lanes.

For instance, a first data lane may be compressible to 50% of its original value as a result of the correlation therein. Further, there may be three other data lanes that are highly uncorrelated and uncompressible, in which case the data lanes altogether may be compressed to 87.5% of their original size via the compression of the first data lane alone. However, while mixing the first data lane with the other data lanes can evenly distribute data in the data lanes, the resulting data within the data lanes may turn out to be highly uncorrelated and uncompressible. In turn, byte rotation may compress the data to 95% of its original size, which is larger than the size that the data lanes would have been compressed to had byte rotation not been used. As such, byte rotation is only helpful in certain instances (e.g., when there is high correlation between the data lanes).

Some other compression techniques have high compressibility but only work with a low throughput (e.g., less than 200 Megabits per second), which is not practical for performant neural network inference engines (e.g., throughput order of 64 Gigabytes per second).

Examples disclosed herein may be used to implement high throughput compression of neural network weights. Examples disclosed herein utilize variable length coding (e.g., lane encoding) to compress neural network weights. In examples disclosed herein, in response to neural network weights being pruned and divided into partitions, variable length coding circuitry identifies sizes of lanes in the partitions. For example, the partitions may be split up into groups of two or more data lanes and the variable length coding circuitry can determine a size in bits for each of the data lanes.

In examples disclosed herein, the variable length coding circuitry determines a slice size based on a size difference between a first data lane including first data (e.g., the largest data lane in the partition) and a second data lane including second data having a smaller size than the first data (e.g., the smallest data lane in the partition). In some examples, the slice size is approximately half of the size difference between the first and second data lanes. In some examples, the slice size is a first slice size in response to the size difference between the first and second data lanes being greater than a first threshold. In some examples, the slice size is a second slice size greater than the first slice size in response to the size difference between the first and second data lanes being greater than a second threshold that is greater than the first threshold.

In examples disclosed herein, the variable length coding circuitry cuts (e.g., removes, extracts, etc.) a portion of the first data from the first data lane based on the slice size. In turn, the variable length coding circuitry relocates the cut portion of the first data by appending the cut portion of the first data to the second data lane. As a result, the first data lane and the second data lane become approximately the same size. In some examples, the variable length coding circuitry appends the cut portion of the first data to an end of the second data lane. As such, the cut portion of the first data follows or is positioned after the second data in the second data lane.

In examples disclosed herein, to indicate the data lane from which data was removed and the data lane to which the data was appended, the variable length coding circuitry assigns a first identifier to the first data lane and a second identifier to the second data lane. For example, the first identifier can be a first header byte positioned at a front of the first data lane and the second identifier can be a second header byte different from the first header byte positioned at a front of the second data lane. In some examples, when there are more than two data lanes in the partition, the variable length coding circuitry assigns a third identifier (e.g., a third header byte) to data lanes not involved in the transaction of data.

To indicate how much data was cut and appended, the variable length coding circuitry records the slice size in the second data lane. For example, the variable length coding circuitry can store the slice size or an activation value corresponding to the slice size between the second data and the second header byte in the second data lane. Specifically, the variable length coding circuitry causes the second data to shift to the right by a predetermined number of bytes (e.g., 5 bytes, 7 bytes, 9 bytes, etc.) to record the header byte and the slice size, or the action value corresponding to the slice size, in front of the second data. As such, the second data lane includes a first section including an identifier indicative of data being appended to the second data lane, a second section indicative of how much data is appended to the second data lane, a third section including the second data, and a fourth section including the cut and appended portion of the first data. In some examples, the second section follows the first section, the third section follows the second section, and the fourth section follows the third section in the second data lane. In some examples, the sections are arranged in a different order.

Sizes (e.g., byte sizes) of the first section and the second section may be predetermined and fixed to enable systematic identification of the identifier associated with the second data lane and the size of the data that is appended to the second data lane when the data lanes in the partition are decoded for subsequent decompression. For example, lane decoding circuitry can determine data was removed from the first data lane in response to identifying the first identifier in the first data lane. Similarly, the lane decoding circuitry can determine data was appended to the second data lane in response to identifying the second identifier in the second data lane. Further, the lane decoding circuitry can identify the slice size in the second data lane. In turn, the lane decoding circuitry can identify the appended data based on the slice size. As such, the lane decoding circuitry can transfer the appended data back to the first data lane.

Accordingly, the data lanes in the partition can be decompressed in response to the data lanes including their original respective data, which allows the neural network to utilize the weights to perform an inference. Additionally, different decompression engines can operate in parallel on different data lanes as the data lanes or portions thereof become decoded. As such, the weights can be decompressed in-line with the neural network performing an inference. For example, a first layer of the weights can be decompressed and utilized by the neural network as a second layer of the weights is decoded. As such, the neural network can operate with a high throughput (e.g., to the order of 64 Gigabytes per second) as weights are decompressed in parallel as the neural network performs the inference, which eliminates or otherwise reduces time that the neural network spends waiting for the weights to be decompressed. That is, in response to the data lanes being decoded, a decompression engine can decompress a first data lane and provide the first data lane to the neural network for processing while decompressing a second data lane in the partition. As such, the neural network does not need to wait for each of the data lanes to be decompressed before beginning to process an input and, thus, the neural network can obtain an inference at a faster rate. Additionally or alternatively, the different decompression engines can decompress each of the partitions at a same time to rapidly obtain all of the decompressed weights and, thus, enable the neural network to perform the inference. Conversely, when using byte rotation to compress the partition, portions of the data lanes need to be de-rotated after being decompressed to obtain the original form of the partition and, thus, values of the weights. Accordingly, the neural network must wait for all of the data lanes in the partition to be decompressed and de-rotated, which forces the neural network to wait for both the decompression and de-rotation of all data lanes to be complete before starting to process an input.

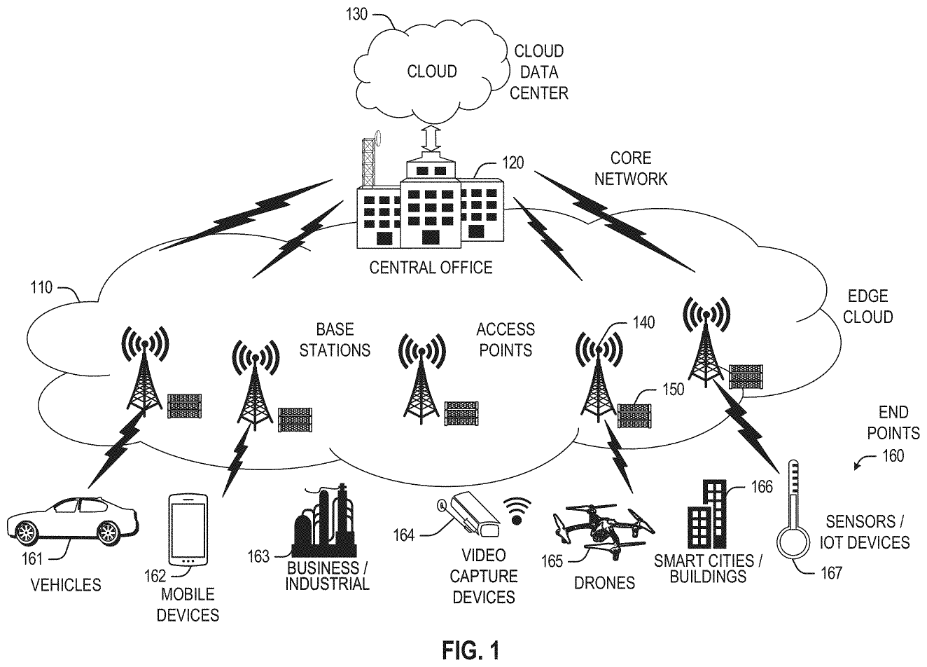

FIG. 1 is a block diagram 100 showing an overview of a configuration for edge computing, which includes a layer of processing referred to in many of the following examples as an “edge cloud”. As shown, the edge cloud 110 is co-located at an edge location, such as an access point or base station 140, a local processing hub 150, or a central office 120, and thus may include multiple entities, devices, and equipment instances. The edge cloud 110 is located much closer to the endpoint (consumer and producer) data sources 160 (e.g., autonomous vehicles 161, user equipment 162, business and industrial equipment 163, video capture devices 164, drones 165, smart cities and building devices 166, sensors and IoT devices 167, etc.) than the cloud data center 130. Compute, memory, and storage resources which are offered at the edges in the edge cloud 110 are critical to providing ultra-low latency response times for services and functions used by the endpoint data sources 160 as well as reduce network backhaul traffic from the edge cloud 110 toward cloud data center 130 thus improving energy consumption and overall network usages among other benefits.

Compute, memory, and storage are scarce resources, and generally decrease depending on the edge location (e.g., fewer processing resources being available at consumer endpoint devices, than at a base station, than at a central office). However, the closer that the edge location is to the endpoint (e.g., user equipment (UE)), the more that space and power is often constrained. Thus, edge computing attempts to reduce the amount of resources needed for network services, through the distribution of more resources which are located closer both geographically and in network access time. In this manner, edge computing attempts to bring the compute resources to the workload data where appropriate, or, bring the workload data to the compute resources.

The following describes aspects of an edge cloud architecture that covers multiple potential deployments and addresses restrictions that some network operators or service providers may have in their own infrastructures. These include, variation of configurations based on the edge location (because edges at a base station level, for instance, may have more constrained performance and capabilities in a multi-tenant scenario); configurations based on the type of compute, memory, storage, fabric, acceleration, or like resources available to edge locations, tiers of locations, or groups of locations; the service, security, and management and orchestration capabilities; and related objectives to achieve usability and performance of end services. These deployments may accomplish processing in network layers that may be considered as “near edge”, “close edge”, “local edge”, “middle edge”, or “far edge” layers, depending on latency, distance, and timing characteristics.

Edge computing is a developing paradigm where computing is performed at or closer to the “edge” of a network, typically through the use of a compute platform (e.g., x86 or ARM compute hardware architecture) implemented at base stations, gateways, network routers, or other devices which are much closer to endpoint devices producing and consuming the data. For example, edge gateway servers may be equipped with pools of memory and storage resources to perform computation in real-time for low latency use-cases (e.g., autonomous driving or video surveillance) for connected client devices. Or as an example, base stations may be augmented with compute and acceleration resources to directly process service workloads for connected user equipment, without further communicating data via backhaul networks. Or as another example, central office network management hardware may be replaced with standardized compute hardware that performs virtualized network functions and offers compute resources for the execution of services and consumer functions for connected devices. Within edge computing networks, there may be scenarios in services which the compute resource will be “moved” to the data, as well as scenarios in which the data will be “moved” to the compute resource. Or as an example, base station compute, acceleration and network resources can provide services in order to scale to workload demands on an as needed basis by activating dormant capacity (subscription, capacity on demand) in order to manage corner cases, emergencies or to provide longevity for deployed resources over a significantly longer implemented lifecycle.

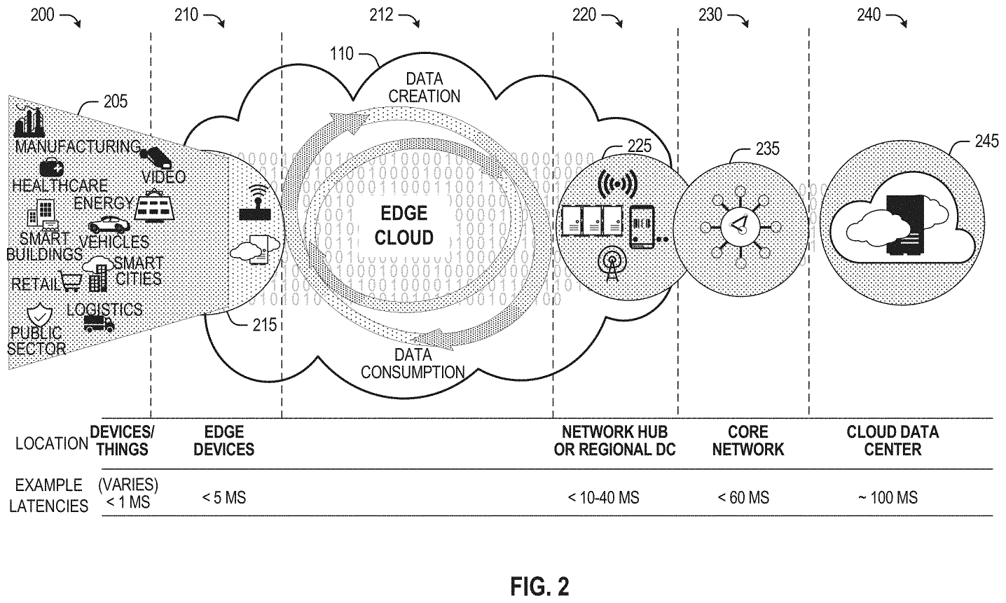

FIG. 2 illustrates operational layers among endpoints, an edge cloud, and cloud computing environments. Specifically, FIG. 2 depicts examples of computational use cases 205, utilizing the edge cloud 110 among multiple illustrative layers of network computing. The layers begin at an endpoint (devices and things) layer 200, which accesses the edge cloud 110 to conduct data creation, analysis, and data consumption activities. The edge cloud 110 may span multiple network layers, such as an edge devices layer 210 having gateways, on-premise servers, or network equipment (nodes 215) located in physically proximate edge systems; a network access layer 220, encompassing base stations, radio processing units, network hubs, regional data centers (DC), or local network equipment (equipment 225); and any equipment, devices, or nodes located therebetween (in layer 212, not illustrated in detail). The network communications within the edge cloud 110 and among the various layers may occur via any number of wired or wireless mediums, including via connectivity architectures and technologies not depicted.

Examples of latency, resulting from network communication distance and processing time constraints, may range from less than a millisecond (ms.) when among the endpoint layer 200, under 5 ms. at the edge devices layer 210, to even between 10 to 40 ms. when communicating with nodes at the network access layer 220. Beyond the edge cloud 110 are core network 230 and cloud data center 240 layers, each with increasing latency (e.g., between 50-60 ms. at the core network layer 230, to 100 or more ms. at the cloud data center layer). As a result, operations at a core network data center 235 or a cloud data center 245, with latencies of at least 50 to 100 ms. or more, will not be able to accomplish many time-critical functions of the use cases 205. Each of these latency values are provided for purposes of illustration and contrast; it will be understood that the use of other access network mediums and technologies may further reduce the latencies. In some examples, respective portions of the network may be categorized as “close edge”, “local edge”, “near edge”, “middle edge”, or “far edge” layers, relative to a network source and destination. For instance, from the perspective of the core network data center 235 or a cloud data center 245, a central office or content data network may be considered as being located within a “near edge” layer (“near” to the cloud, having high latency values when communicating with the devices and endpoints of the use cases 205), whereas an access point, base station, on-premise server, or network gateway may be considered as located within a “far edge” layer (“far” from the cloud, having low latency values when communicating with the devices and endpoints of the use cases 205). It will be understood that other categorizations of a particular network layer as constituting a “close”, “local”, “near”, “middle”, or “far” edge may be based on latency, distance, number of network hops, or other measurable characteristics, as measured from a source in any of the network layers 200-240.

The various use cases 205 may access resources under usage pressure from incoming streams, due to multiple services utilizing the edge cloud. To achieve results with low latency, the services executed within the edge cloud 110 balance varying requirements in terms of: (a) Priority (throughput or latency) and Quality of Service (QoS) (e.g., traffic for an autonomous car may have higher priority than a temperature sensor in terms of response time requirement; or, a performance sensitivity/bottleneck may exist at a compute/accelerator, memory, storage, or network resource, depending on the application); (b) Reliability and Resiliency (e.g., some input streams need to be acted upon and the traffic routed with mission-critical reliability, where as some other input streams may be tolerate an occasional failure, depending on the application); and (c) Physical constraints (e.g., power, cooling and form-factor).

The end-to-end service view for these use cases involves the concept of a service-flow and is associated with a transaction. The transaction details the overall service requirement for the entity consuming the service, as well as the associated services for the resources, workloads, workflows, and business functional and business level requirements. The services executed with the “terms” described may be managed at each layer in a way to assure real time, and runtime contractual compliance for the transaction during the lifecycle of the service. When a component in the transaction is missing its agreed to SLA, the system as a whole (components in the transaction) may provide the ability to (1) understand the impact of the SLA violation, and (2) augment other components in the system to resume overall transaction SLA, and (3) implement steps to remediate.

Thus, with these variations and service features in mind, edge computing within the edge cloud 110 may provide the ability to serve and respond to multiple applications of the use cases 205 (e.g., object tracking, video surveillance, connected cars, etc.) in real-time or near real-time, and meet ultra-low latency requirements for these multiple applications. These advantages enable a whole new class of applications (Virtual Network Functions (VNFs), Function as a Service (FaaS), Edge as a Service (EaaS), standard processes, etc.), which cannot leverage conventional cloud computing due to latency or other limitations.

However, with the advantages of edge computing comes the following caveats. The devices located at the edge are often resource constrained and therefore there is pressure on usage of edge resources. Typically, this is addressed through the pooling of memory and storage resources for use by multiple users (tenants) and devices. The edge may be power and cooling constrained and therefore the power usage needs to be accounted for by the applications that are consuming the most power. There may be inherent power-performance tradeoffs in these pooled memory resources, as many of them are likely to use emerging memory technologies, where more power requires greater memory bandwidth. Likewise, improved security of hardware and root of trust trusted functions are also required, because edge locations may be unmanned and may even need permissioned access (e.g., when housed in a third-party location). Such issues are magnified in the edge cloud 110 in a multi-tenant, multi-owner, or multi-access setting, where services and applications are requested by many users, especially as network usage dynamically fluctuates and the composition of the multiple stakeholders, use cases, and services changes.

At a more generic level, an edge computing system may be described to encompass any number of deployments at the previously discussed layers operating in the edge cloud 110 (network layers 200-240), which provide coordination from client and distributed computing devices. One or more edge gateway nodes, one or more edge aggregation nodes, and one or more core data centers may be distributed across layers of the network to provide an implementation of the edge computing system by or on behalf of a telecommunication service provider (“telco”, or “TSP”), internet-of-things service provider, cloud service provider (CSP), enterprise entity, or any other number of entities. Various implementations and configurations of the edge computing system may be provided dynamically, such as when orchestrated to meet service objectives.

Consistent with the examples provided herein, a client compute node may be embodied as any type of endpoint component, device, appliance, or other thing capable of communicating as a producer or consumer of data. Further, the label “node” or “device” as used in the edge computing system does not necessarily mean that such node or device operates in a client or agent/minion/follower role; rather, any of the nodes or devices in the edge computing system refer to individual entities, nodes, or subsystems which include discrete or connected hardware or software configurations to facilitate or use the edge cloud 110.

As such, the edge cloud 110 is formed from network components and functional features operated by and within edge gateway nodes, edge aggregation nodes, or other edge compute nodes among network layers 210-230. The edge cloud 110 thus may be embodied as any type of network that provides edge computing and/or storage resources which are proximately located to radio access network (RAN) capable endpoint devices (e.g., mobile computing devices, IoT devices, smart devices, etc.), which are discussed herein. In other words, the edge cloud 110 may be envisioned as an “edge” which connects the endpoint devices and traditional network access points that serve as an ingress point into service provider core networks, including mobile carrier networks (e.g., Global System for Mobile Communications (GSM) networks, Long-Term Evolution (LTE) networks, 5G/6G networks, etc.), while also providing storage and/or compute capabilities. Other types and forms of network access (e.g., Wi-Fi, long-range wireless, wired networks including optical networks) may also be utilized in place of or in combination with such 3GPP carrier networks.

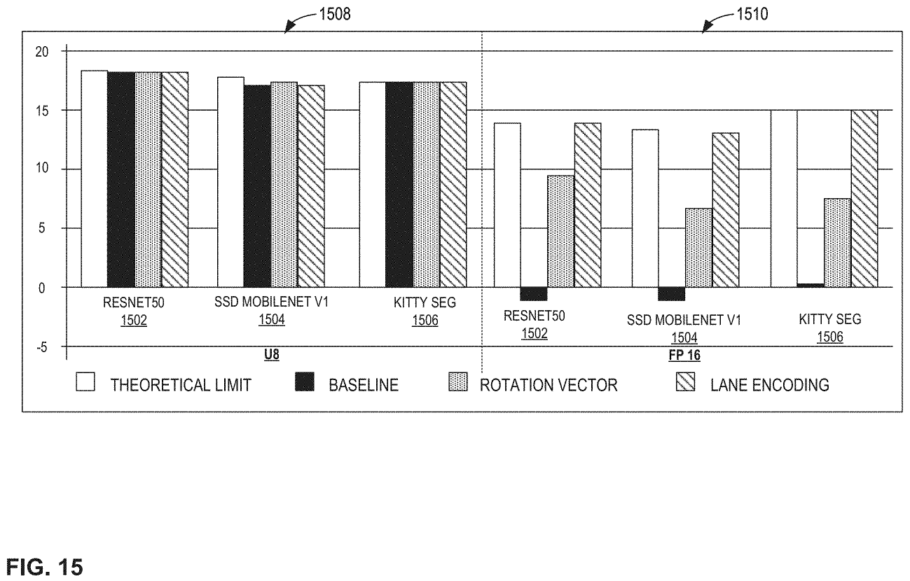

The network components of the edge cloud 110 may be servers, multi-tenant servers, appliance computing devices, and/or any other type of computing devices. For example, the edge cloud 110 may include an appliance computing device that is a self-contained electronic device including a housing, a chassis, a case, or a shell. In some circumstances, the housing may be dimensioned for portability such that it can be carried by a human and/or shipped. Example housings may include materials that form one or more exterior surfaces that partially or fully protect contents of the appliance, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. Example housings and/or surfaces thereof may include or connect to mounting hardware to enable attachment to structures such as buildings, telecommunication structures (e.g., poles, antenna structures, etc.) and/or racks (e.g., server racks, blade mounts, etc.). Example housings and/or surfaces thereof may support one or more sensors (e.g., temperature sensors, vibration sensors, light sensors, acoustic sensors, capacitive sensors, proximity sensors, etc.). One or more such sensors may be contained in, carried by, or otherwise embedded in the surface and/or mounted to the surface of the appliance. Example housings and/or surfaces thereof may support mechanical connectivity, such as propulsion hardware (e.g., wheels, propellers, etc.) and/or articulating hardware (e.g., machine arms, pivotable appendages, etc.). In some circumstances, the sensors may include any type of input devices such as user interface hardware (e.g., buttons, switches, dials, sliders, etc.). In some circumstances, example housings include output devices contained in, carried by, embedded therein and/or attached thereto. Output devices may include displays, touchscreens, lights, LEDs, speakers, I/O ports (e.g., USB), etc. In some circumstances, edge devices are devices presented in the network for a specific purpose (e.g., a traffic light), but may have processing and/or other capacities that may be utilized for other purposes. Such edge devices may be independent from other networked devices and may be provided with a housing having a form factor suitable for its primary purpose; yet be available for other compute tasks that do not interfere with its primary task. Edge devices include Internet of Things devices. The appliance computing device may include hardware and software components to manage local issues such as device temperature, vibration, resource utilization, updates, power issues, physical and network security, etc. Example hardware for implementing an appliance computing device is described in conjunction with FIG. 15. The edge cloud 110 may also include one or more servers and/or one or more multi-tenant servers. Such a server may include an operating system and implement a virtual computing environment. A virtual computing environment may include a hypervisor managing (e.g., spawning, deploying, destroying, etc.) one or more virtual machines, one or more containers, etc. Such virtual computing environments provide an execution environment in which one or more applications and/or other software, code or scripts may execute while being isolated from one or more other applications, software, code, or scripts.

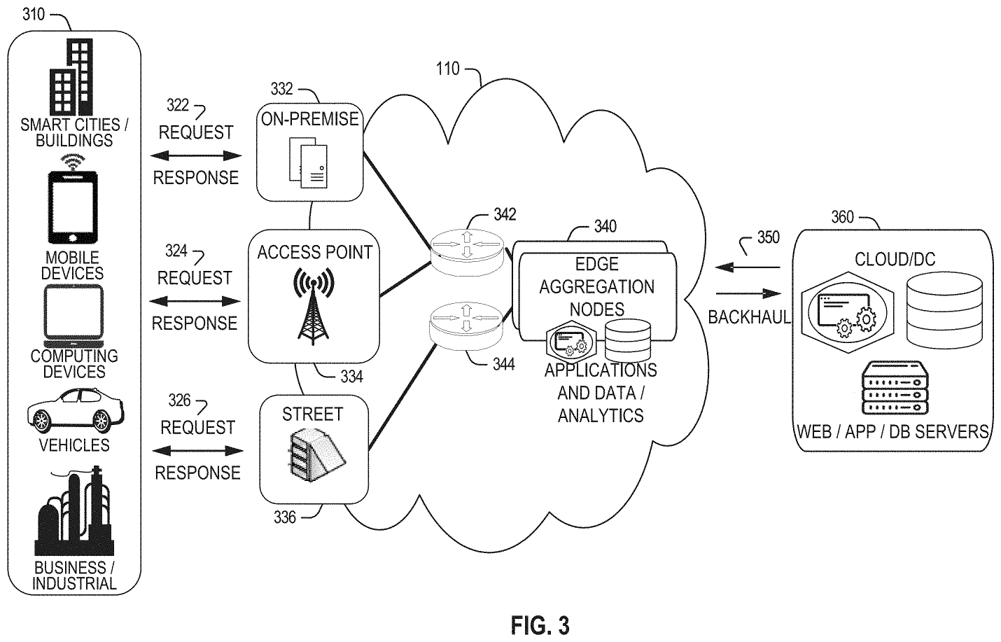

In FIG. 3, various client endpoints 310 (in the form of mobile devices, computers, autonomous vehicles, business computing equipment, industrial processing equipment) exchange requests and responses that are specific to the type of endpoint network aggregation. For instance, client endpoints 310 may obtain network access via a wired broadband network, by exchanging requests and responses 322 through an on-premise network system 332. Some client endpoints 310, such as mobile computing devices, may obtain network access via a wireless broadband network, by exchanging requests and responses 324 through an access point (e.g., cellular network tower) 334. Some client endpoints 310, such as autonomous vehicles may obtain network access for requests and responses 326 via a wireless vehicular network through a street-located network system 336. However, regardless of the type of network access, the TSP may deploy aggregation points 342, 344 within the edge cloud 110 to aggregate traffic and requests. Thus, within the edge cloud 110, the TSP may deploy various compute and storage resources, such as at edge aggregation nodes 340, to provide requested content. The edge aggregation nodes 340 and other systems of the edge cloud 110 are connected to a cloud or data center 360, which uses a backhaul network 350 to fulfill higher-latency requests from a cloud/data center for websites, applications, database servers, etc. Additional or consolidated instances of the edge aggregation nodes 340 and the aggregation points 342, 344, including those deployed on a single server framework, may also be present within the edge cloud 110 or other areas of the TSP infrastructure.

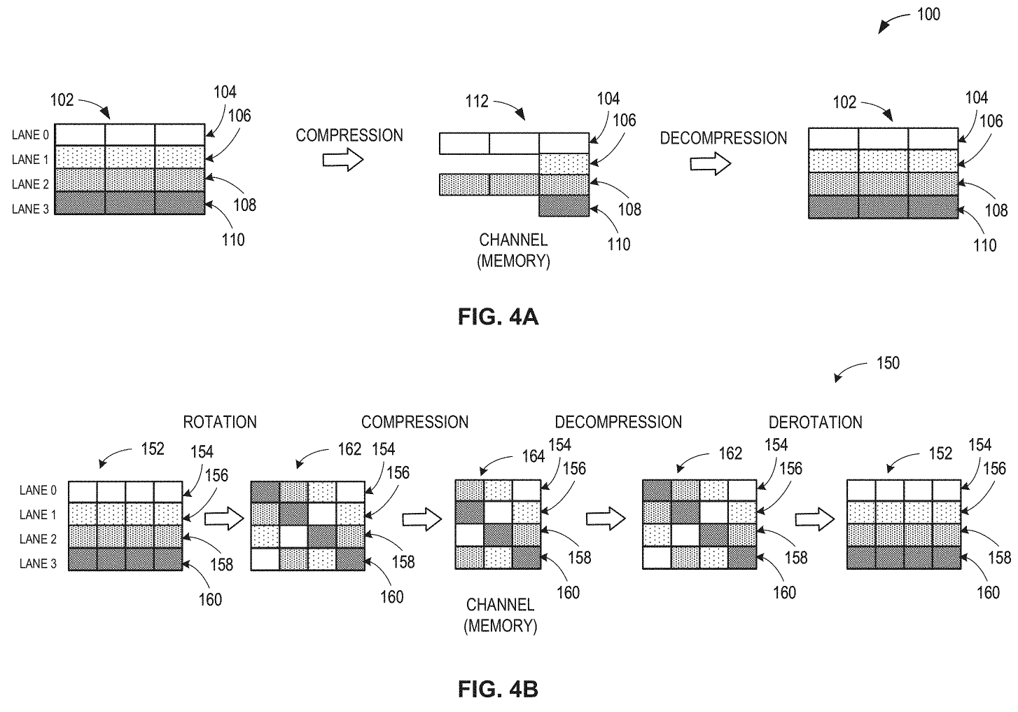

FIG. 4A illustrates a first prior art process 400 (e.g., a baseline) of compressing neural network weights. In the illustrated example of FIG. 4A, a first partition 402 includes a first lane (“LANE 0”) 404, a second lane (“LANE 1”) 406, a third lane (“LANE 2”) 208, and a fourth lane (“LANE 3”) 210 of data (e.g., neural network weights) that undergoes compression. However, the lanes 404, 406, 408, 410 of the illustrated example have different probability density functions and, in turn, different compression ratios. In the illustrated example of FIG. 4A, in response to undergoing compression, the first lane 404 and the third lane 408 remain approximately the same size as before compression while the second lane 406 and the fourth lane 410 are compressed to approximately a third of their original sizes. As such, the first lane 404 and the third lane 408 form memory bubbles and, in turn, dictate a minimum bandwidth required to store the first partition 402 in a compressed form 412.

FIG. 4B illustrates a second prior art process 450 (e.g., byte rotation) of compressing neural network weights. In the illustrated example of FIG. 4B, a second partition 452 includes a first lane (“LANE 0”) 454, a second lane (“LANE 1”) 456, a third lane (“LANE 2”) 458, and a fourth lane (“LANE 3”) 460 of data (e.g., neural network weights) that undergoes compression. When utilizing byte rotation 450, data is rotated (e.g., mixed) between the lanes 454, 456, 458, 460 to evenly distribute the data. For example, when the partition 452 is in a rotated form 462, the first lane 454 includes data originally from the first lane 454, the second lane 456, the third lane 458, and the fourth lane 460. In response to the data being rotated, the partition 452 is compressed. In the illustrated example, there is correlation in the data within the lanes 454, 456, 458, 460, which allows the partition 452 to be compressed to 75% of its original size in a compressed form 464. However, in other instances, there may be minimal or otherwise reduced correlation between the data within the lanes 454, 456, 458, 460, which inhibits the compressibility of the lanes 454, 456, 458, 460 and, thus, increases the bandwidth required to store the partition 452 in the compressed form 464.

In the illustrated example of FIG. 4B, when a neural network associated with the partition 452 is to perform an inference, the compressed form 464 of the partition 452 is retrieved from a memory channel and decompressed to obtain the rotated form 462 of the partition 452. Further, the rotated form 462 of the partition 452 is de-rotated (e.g., encounters a rotation in a reverse direction from the rotation that obtained the rotated form 462) to obtain the original partition 452 of the neural network weights, which the neural network can then utilize to perform an inference.

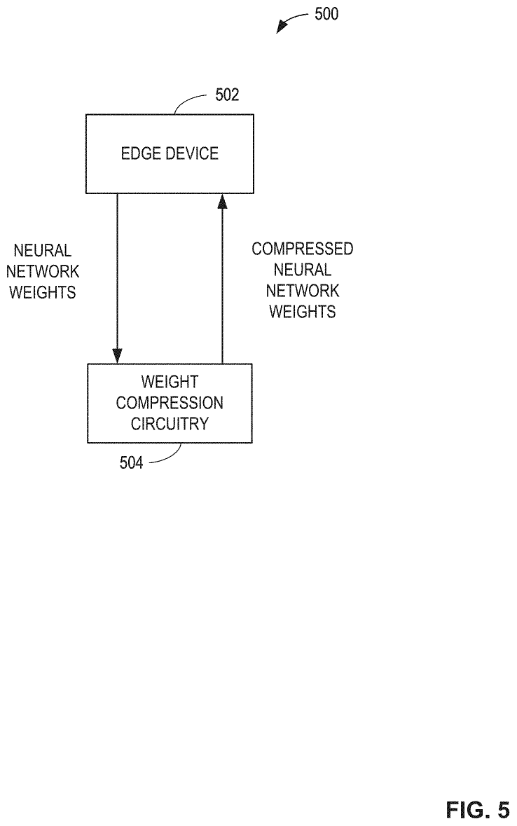

FIG. 5 is a block diagram of an example system 500 that performs high throughput compression of neural network weights in accordance with the teachings disclosed herein. In the illustrated example of FIG. 5, the system 500 includes an edge device 502 and weight compression circuitry 504. In FIG. 5, the example edge device 502 utilizes a neural network to perform an inference based on an input. For example, the edge device 502 can be in connection with a vehicle, a manufacturing machine, and/or a video camera, which provide inputs to the edge device 502 and, in turn, the example edge device 502 deduces an inference. Additionally or alternatively, the example weight compression circuitry 504 can be in connection with a server that utilizes a neural network. However, resources associated with the example edge device 502, or a server, are constrained by computational, memory, and bandwidth requirements.

In the illustrated example of FIG. 5, the weight compression circuitry 504 compresses the weights in the neural network associated with the edge device 502. In some examples, the weight compression circuitry 504 receives the neural network weights in response to the neural network being trained. In some examples, the weight compression circuitry 504 compresses the neural network weights offline and transmits the compressed weights back to the edge device 502. In FIG. 5, the example edge device 502 stores the compressed weights in a memory associated therewith. As such, the example weight compression circuitry 504 minimizes or otherwise reduces an amount of space that the neural network weights require in the edge device 502. Accordingly, the example weight compression circuitry 504 can enable the edge device 502 to have enough bandwidth to implement a complex neural network and/or other processing components that contribute to the functionality of the edge device 502. The edge device 502 and the weight compression circuitry 504 of the illustrated example are described in further detail in the examples disclosed herein.

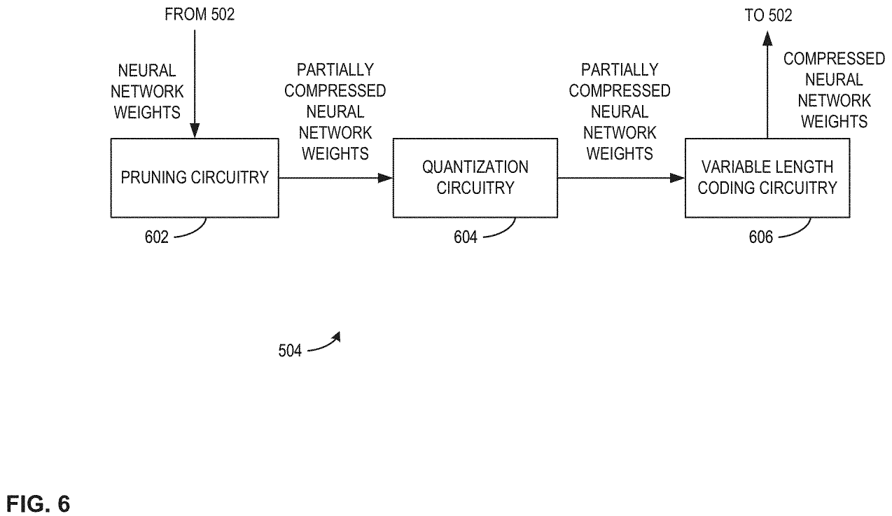

FIG. 6 is a block diagram of the example weight compression circuitry 504 of FIG. 5. In FIG. 6, the example weight compression circuitry 504 includes pruning circuitry 602, quantization circuitry 604, and variable length coding circuitry 606. In the illustrated example of FIG. 6, the example pruning circuitry 602 accesses neural network weights from the edge device 502 of FIG. 5. In FIG. 6, the pruning circuitry 602 prunes the neural network weights that are below a threshold value. The neural network associated with the example edge device 502 is trained to re-learn the weights that are below the threshold during a training period. As such, an accuracy of the neural network weights is not compromised by the example pruning circuitry 602. In FIG. 6, the example pruning circuitry 602 transmits the neural network weights that remain after pruning (e.g., that are above the threshold value) to the quantization circuitry 604.

In the illustrated example of FIG. 6, the quantization circuitry 604 reduces an amount of bits required to store each neural network weight. Specifically, the example quantization circuitry 604 partitions the neural network weights to enable the weights to be shared between neurons of a same layer in the neural network of the edge device 502.

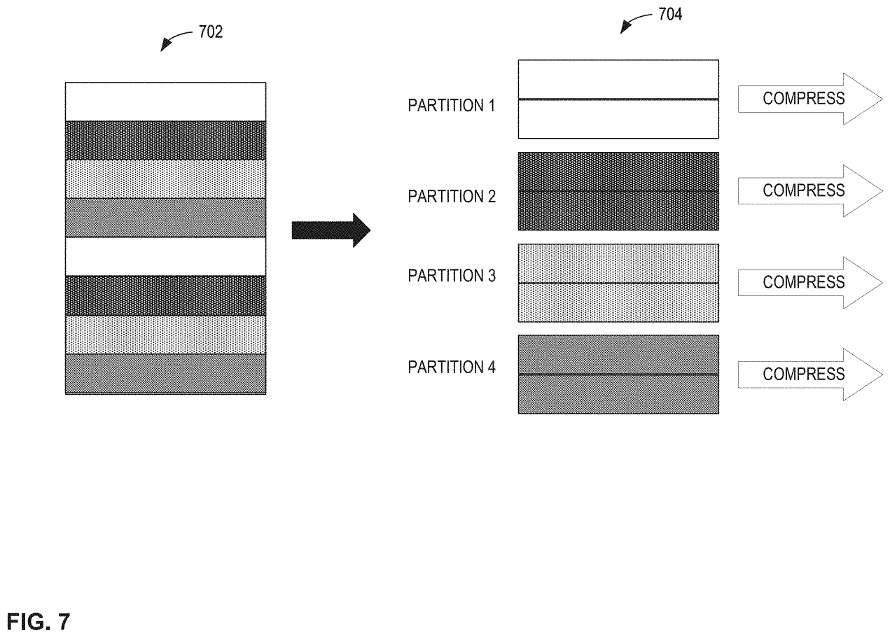

The partitioning executed by the example quantization circuitry 604 is illustrated in FIG. 7. In the illustrated example of FIG. 7, the quantization circuitry 604 converts pruned weights 702 to multi-lane byte partitions 704. Further, the example quantization circuitry 604 transmits the byte partitions 704 to the variable length coding circuitry 606 for further compression.

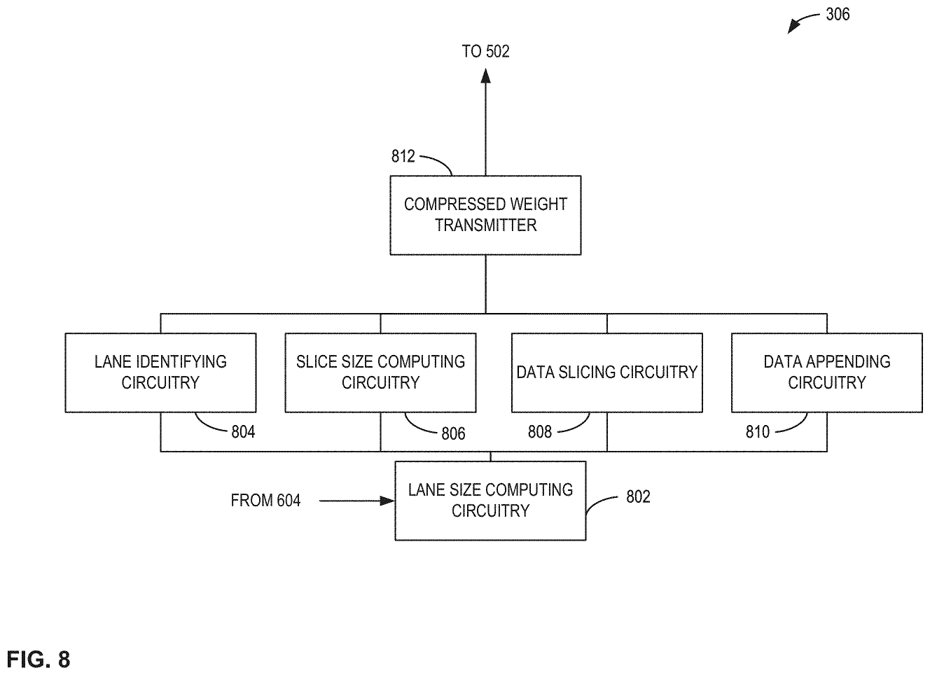

Returning to the illustrated example of FIG. 6, to compress partitions obtained via the quantization circuitry 604 (e.g., the byte partitions 704), the variable length coding circuitry 606 identifies sizes of data lanes in the respective partitions. In FIG. 6, the example variable length coding circuitry 606 compresses the data in the data lanes, which is representative of the neural network weights. Specifically, the example variable length coding circuitry 606 moves data between the data lanes based on a size relationship of the data lanes, as discussed further in association with FIG. 8. In turn, the example variable length coding circuitry 606 transmits the compressed neural network weights to the edge device 502 as data lanes in partitions.

FIG. 8 is a block diagram of the example variable length coding circuitry 606 of FIG. 6. In the illustrated example of FIG. 8, the variable length coding circuitry 606 includes lane size computing circuitry 802, lane identifying circuitry 804, slice size computing circuitry 806, data slicing circuitry 808, data appending circuitry 810, and a compressed weight transmitter 812.

In the illustrated example of FIG. 8, the lane size computing circuitry 802 obtains partially compressed neural network weights via the quantization circuitry 604. Specifically, the lane size computing circuitry 802 accesses partitions representative of the neural network weights. In FIG. 8, the example lane size computing circuitry 802 determines sizes of respective data lanes in a partition of neural network weights. For example, the lane size computing circuitry 802 can compute the sizes of each of the data lanes in bytes in response to receiving the partition. In examples disclosed herein, partitions may include two or more data lanes.

In the illustrated example of FIG. 8, the lane identifying circuitry 804 assigns an identifier to each of the data lanes in the partition. For example, the lane identifying circuitry 804 can shift data in the respective data lanes to the right or left by a predetermined amount (e.g., 1 byte, 2 bytes, 4 bytes, etc.) and insert the identifier in the byte(s) at the right or left end of the data lane.

In the illustrated example of FIG. 8, the lane identifying circuitry 804 assigns the identifiers as header bytes (e.g., a value in the first byte of the data lane). Additionally or alternatively, the example lane identifying circuitry 804 can assign the identifiers as footer bytes (e.g., a value in the last byte of the data lane). In some examples, the example lane identifying circuitry 804 assigns the identifiers as header or footer bits. In FIG. 8, the example lane identifying circuitry 804 determines the header bytes to assign to the respective data lanes based on the sizes of the respective data lanes. For example, the lane identifying circuitry 804 can assign a first header byte to the largest data lane (e.g., the data lane with the most bytes) in the partition. Further, the example lane identifying circuitry 804 can assign a second header byte to the smallest data lane (e.g., the data lane with the least bytes) in the partition. In some examples, when the partition includes more than two data lanes, the lane identifying circuitry 804 assigns a third header byte to data lanes that have a size between the largest data lane and the smallest data lane.

In the illustrated example of FIG. 8, the slice size computing circuitry 806 determines an amount of data (e.g., a slice size) to be moved from a first data lane in a partition (e.g., the largest data lane in the partition) to a second data lane in the partition (e.g., the smallest data lane in the partition). In FIG. 8, the example slice size computing circuitry 806 determines the slice size based on a size difference between the first data lane and the second data lane. In some examples, the slice size computing circuitry 806 computes the slice size to be approximately half of the size difference between the first data lane and the second data lane.

In some examples, the slice size computing circuitry 806 generates activation links for predetermined slice sizes. For example, the activation links can be represented as values linked to sizes of the predetermined slices. That is, the example slice size computing circuitry 806 can assign a first activation link to a first predetermined slice size. Further, the example slice size computing circuitry 806 can assign a second activation link different from the first activation link to a second predetermined slice size different from the first predetermined slice size. In some examples, the slice size computing circuitry 806 assigns a first size difference threshold to the first predetermined slice size and assigns a second size difference threshold to the second predetermined slice size. In some examples, in response to the size difference between the first data lane and the second data lane satisfying (e.g., being greater than) the first size difference threshold and not satisfying (e.g., being less than) the second size difference threshold, the slice size computing circuitry 806 computes the slice size to be the first predetermined slice size. In some examples, in response to the size difference between the first data lane and the second data lane satisfying the first and second size difference threshold, the slice size computing circuitry 806 computes the slices size to be the second predetermined slice size. Accordingly, the example slice size computing circuitry 806 can utilize any number of predetermined slice sizes linked to respective size difference thresholds and/or activation links. In some examples, the slice size computing circuitry 806 identifies a slice size to utilize based on a predetermined slice size that is closest to half of the size difference between the first data lane and the second data lane.

In FIG. 8, the example slice size computing circuitry 806 shifts the data in the second data lane to create space for the value of the slice size to be recorded in the second data lane. For example, the slice size computing circuitry 806 can shift the original data associated with the second data lane (e.g., the data following the header byte) to the right by a predetermined amount of bytes (e.g., 2 bytes, 4 bytes, 6 bytes, etc.). In FIG. 8, the example slice size computing circuitry 806 stores a value indicative of the slice size in the predetermined amount of bytes following the header byte. In some examples, the value indicative of the slice size is an activation code linked to the slice size. In some examples, the value indicative of the slice size is the value of the slice size in bytes. Additionally or alternatively, the slice size computing circuitry 806 can shift the original data associated with the second data lane to the left by a predetermined amount of bytes (e.g., 2 bytes, 4 bytes, 6 bytes, etc.) in response to the identifier for the second data lane being at the end of the data lane instead of the front of the data lane (e.g., when the identifier is a footer instead of a header) and store the value indicative of the slice in front of the identifier.

In FIG. 8, to compress the largest data lane in the partition, the example data slicing circuitry 808 slices (e.g., cuts, removes, etc.) a portion of the data from the largest data lane based on the slice size determined by the slice size computing circuitry 806. For example, the data slicing circuitry 808 can cut an amount of data corresponding to the slice size from an end of the data in the largest data lane. In some examples, the data slicing circuitry 808 cuts the slice size amount of data from the front of the data lane (e.g., after the identifier when the identifier is a header byte or the beginning of the data lane when the identifier is not a header byte).

In FIG. 8, the example data appending circuitry 810 appends the portion of the data that was removed from the largest data lane to the smallest data lane in the partition. In some examples, the data appending circuitry 810 appends the portion of the data removed from the largest data lane to an end of the smallest data lane. In some examples, the data appending circuitry 810 appends the portion of the data removed from the largest data lane to a front of the data lane (e.g., after the identifier when the identifier is a header byte or the beginning of the data lane when the identifier is not a header byte). In some examples, the data appending circuitry 810 appends the portion of the data removed from the largest data lane adjacent to the value indicative of the slice size in the smallest data lane. Accordingly, the example data appending circuitry 810 causes the size of what was originally the largest data lane to be approximately equivalent to the size of what was originally the smallest data lane. Thus, a memory bandwidth of the compressed partition is not overly limited by the largest data lane in the partition. Specifically, the size of what was originally the largest data lane may still remain slightly larger than the size of what was originally the smallest data lane as a result of rounding that may occur when computing the slice size. Accordingly, the memory bandwidth utilized to store the partition may still be based on the largest data lane.

In FIG. 8, the example compressed weight transmitter 812 transmits the partition to the edge device 502 of FIG. 5. As such, the example edge device 502 can store the compressed version of the neural network weights as partitions created via the quantization circuitry 604 and further compressed via the variable length coding circuitry 606 to minimize or otherwise reduce an amount of space required by the neural network on the edge device 502. Moreover, the example edge device 502 can access and decompress the partitions when the neural network is in use, as discussed in further detail below.

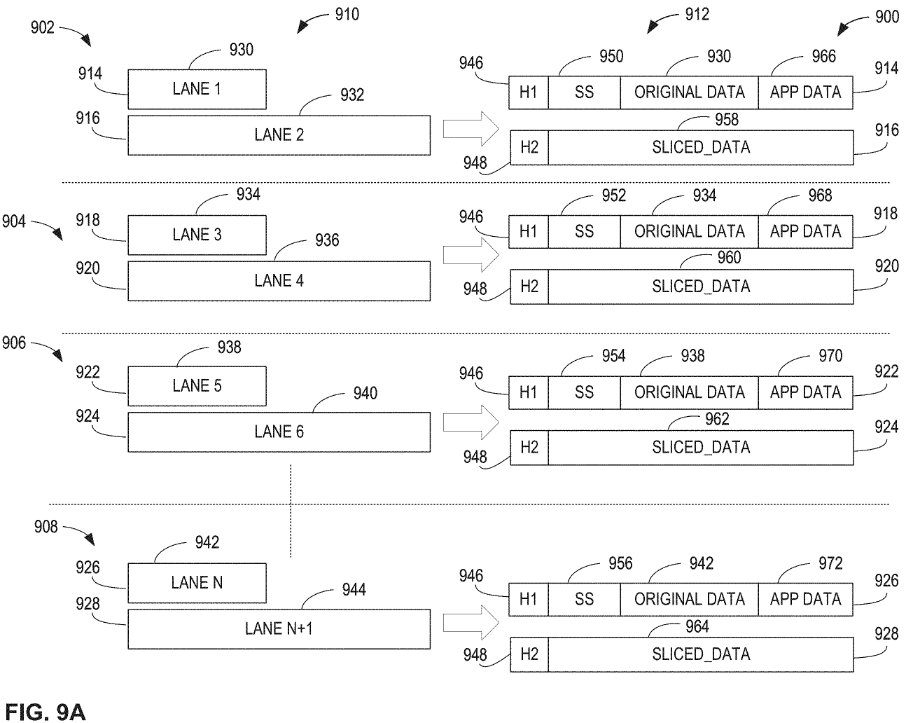

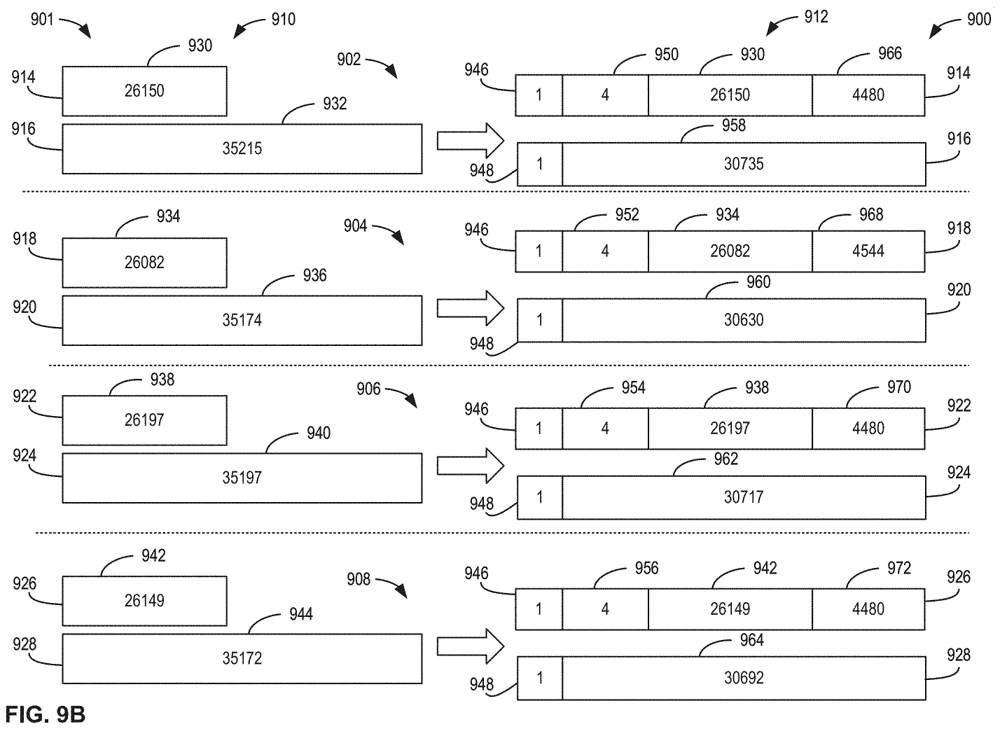

FIG. 9A illustrates example neural network weights 900 before and after being compressed by the variable length coding circuitry 606. The illustrated example of FIG. 9A depicts a first example partition 902, a second example partition 904, a third example partition 906, and a fourth example partition 908. Specifically, the illustrated example includes a first version 910 (e.g., a partially compressed version) of the partitions 902, 904, 906, 908 prior to the partitions 902, 904, 906, 908 being processed by the variable length coding circuitry 606 and a second version 912 (e.g., a fully compressed version) of the partitions 902, 904, 906, 908 in response to the partitions 902, 904, 906, 908 being processed by the variable length coding circuitry 606.

In the illustrated example of FIG. 9A, the first partition 902 includes a first data lane 914 and a second data lane 916, the second partition 904 includes a third data lane 918 and a fourth data lane 920, the third partition 906 includes a fifth data lane 922 and a sixth data lane 924, and the fourth partition 908 includes a seventh data lane 926 and an eighth data lane 928. In the example partially compressed version 910 of the partitions 902, 904, 906, 908, the first, third, fifth, and seventh data lanes 914, 918, 922, 926 have a smaller size than the second, fourth, sixth, and eighth data lanes 916, 920, 924, 928. In FIG. 9A, the example partially compressed version 910 of each of the data lanes 914, 916, 918, 920, 922, 924, 926, 928 consists of respective original data 930, 932, 934, 936, 938, 940, 942, 944.

In the illustrated example of FIG. 9A, the variable length coding circuitry 606 compresses the second, fourth, sixth, and eighth data lanes 916, 920, 924, 928 such that the data lanes 914, 916, 918, 920, 922, 924, 926, 928 in the respective partitions 902, 904, 906, 908 have approximately equal sizes. Thus, the example variable length coding circuitry 606 eliminates or otherwise reduces a memory bubble that would otherwise result from a size difference between different sized data lanes in a same partition and, in turn, minimizes or otherwise reduces an amount of space used to store the neural networks in compressed form on the edge device 502.

In the illustrated example of FIG. 9A, to identify the data lanes 914, 916, 918, 920, 922, 924, 926, 928 that have a smaller size of original data 930, 932, 934, 936, 938, 940, 942, 944, the variable length coding circuitry 606 assigns each of the first, third, fifth, and seventh data lanes 914, 918, 922, 926, a first header byte 946 (“H1”). Accordingly, to identify the data lanes 914, 916, 918, 920, 922, 924, 926, 928 that have a larger size of original data, the example variable length coding circuitry 606 assigns each of the second, fourth, sixth, and eighth data lanes 916, 920, 924, 928 a second header byte 948 (“H2”) different from the first header byte 946.

In the illustrated example of FIG. 9A, the variable length coding circuitry 606 determines an amount of data to cut from the original data 932, 936, 940, 944 of the larger data lanes 916, 920, 924, 928 based on a size difference between the original data 930, 934, 938, 942 in the smaller data lanes 914, 918, 922, 926 and the original data 932, 936, 940, 944 in the larger data lanes 916, 920, 924, 928 in the respective partitions 902, 904, 906, 908. In turn, the example variable length coding circuitry 606 stores slice sizes (e.g., data sizes, activation values corresponding to data sizes) (“SS”) 950, 952, 954, 956 in the compressed version 912 of the smaller data lanes 914, 918, 922, 926. Specifically, the example variable length coding circuitry 606 records the slice sizes 950, 952, 954, 956 between the respective header bytes 946 and the respective original data 930, 934, 938, 942 associated with the smaller data lanes 914, 918, 922, 926.

In FIG. 9A, the example variable length coding circuitry 606 maintains first portions (“SLICED_DATA”) 958, 960, 962, 964 of the original data 932, 936, 940, 944 associated with the larger data lanes 916, 920, 924, 928 in the respective larger data lanes 916, 920, 924, 928. Specifically, the example variable length coding circuitry 606 removes the first portions 958, 960, 962, 964 of the original data 932, 936, 940, 944 associated with the larger data lanes 916, 920, 924, 928 from respective ends (e.g., right ends) of the original data 932, 936, 940, 944 in the larger data lanes 916, 920, 924, 928. Further, the example variable length coding circuitry 606 cuts second portions (“APP DATA”) 966, 968, 970, 972 from the original data 932, 936, 940, 944 in the respective larger data lanes 916, 920, 924, 928 based on the slice sizes 950, 952, 954, 956 (e.g., a number of bytes that corresponds to the slice sizes 950, 952, 954, 956). In turn, the example variable length coding circuitry 606 appends the second portions 966, 968, 970, 972 of the original data 932, 936, 940, 944 of the respective larger data lanes 916, 920, 924, 928 to the smaller data lanes 914, 918, 922, 926 in the respective partitions 902, 904, 906, 908 associated with the larger data lanes 916, 920, 924, 928. Specifically, the example variable length coding circuitry 606 appends the second portions 966, 968, 970, 972 to ends of the smaller data lanes 914, 918, 922, 926 such that the second portions 966, 968, 970, 972 follow the original data 930, 934, 938, 942 associated with the respective smaller data lanes 914, 918, 922, 926.

FIG. 9B illustrates byte sizes 601 of the various portions of data in the partitions 902, 904, 906, 908 of FIG. 9A. In the illustrated example of FIG. 9B, although the first header byte 946 and the second header byte 948 have different values, the header bytes 946, 948 are each one byte. Similarly, although the slice sizes 950, 952, 954, 956 do not each have the same value, the slice sizes 950, 952, 954, 956 are indicated via a predetermined number of bytes, which is four bytes in the illustrated example of FIG. 9B. Because the header bytes 946, 948 and the slice sizes 950, 952, 954, 956 are each predetermined sizes, an exact position of the header bytes 946, 948 (e.g., a beginning and an end of the header bytes 946, 948) and the slice sizes 950, 952, 954, 956 can be quickly identified when the partitions 902, 904, 906, 908 are being decompressed, which at least partially enables the neural network weights 900 to be decompressed as the associated neural network processes information.

In the illustrated example of FIG. 9B, the slice sizes 950, 954, 956 associated with the first, third, and fourth partitions 902, 906, 908 each have a same value indicative of 4480 bytes of data being moved from the ends of the respective original data 932, 940, 944 in the larger data lanes 916, 924, 928 to ends of the respective smaller data lanes 614, 622, 626. Accordingly, the slice size 952 associated with the second partition 904 has a second value indicative of 4544 bytes being moved from the end of the original data 936 in the larger data lane 920 of the second partition 904 to the end of the smaller data lane 918. In particular, each of the slice sizes 950, 954, 956 associated with the first, third, and fourth partitions 902, 906, 908 is 4480 because respective halves the size differences between the original data 930, 938, 942 in the smaller data lanes 914, 922, 926 and the original data 932, 940, 944 are each greater than 4480 (e.g., a first threshold) and less than 4544 (e.g., a second threshold. Accordingly, the slice size 952 associated with the second partition 904 is 4544 because half of the size difference between the original data 934 in the smaller data lane 918 and the original data 936 in the larger data lane is greater than 4544 (e.g., the second threshold) and less than a next greatest threshold.

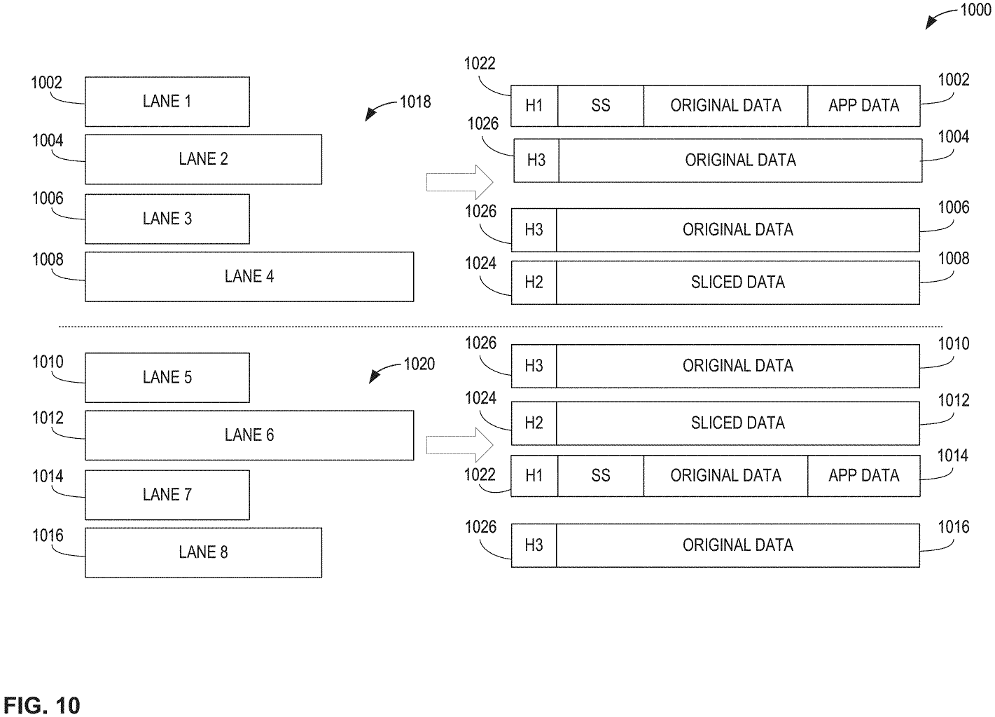

FIG. 10 illustrates another example of neural network weights 1000 before and after being compressed by the variable length coding circuitry 606. To avoid being overly redundant, aspects in FIG. 10 identical to the compression of the neural network weights 900 in FIGS. 9A-B will not be discussed in detail and, instead, only differences that arise as a result of different partition sizes from those shown in FIGS. 9A-B will be discussed.

In the illustrated example of FIG. 10, the quantization circuitry 604 divides a first data lane 1002, a second data lane 1004, a third data lane 1006, a fourth data lane 1008, a fifth data lane 1010, a sixth data lane 1012, a seventh data lane 1014, and an eighth data lane 1016 equally amongst a first partition 1018 and a second partition 1020. In FIG. 10, the example variable length coding circuitry 606 identifies the data lanes 1002, 1004, 1006, 1008, 1010, 1012, 1014, 1016 having the smallest and largest sizes in the respective partitions 1018, 1020. As such, the example variable length coding circuitry 606 identifies the smallest and largest data lanes in the first partition 1018 to be the first data lane 1002 and the fourth data lane 1008, respectively. Similarly, the example variable length coding circuitry 606 identifies the smallest and largest data lanes in the second partition 1020 as the seventh data lane 1014 and the sixth data lane 1012, respectively. Accordingly, to identify the smallest of the data lanes 1002, 1004, 1006, 1008, 1010, 1012, 1014, 1016 in the partitions 1018, 1020, the variable length coding circuitry 606 assigns a first header 1022 to the first data lane 1002 and the seventh data lane 1014. Likewise, to identify the largest of the data lanes 1002, 1004, 1006, 1008, 1010, 1012, 1014, 1016 in the partitions 1018, 1020, the variable length coding circuitry 606 assigns a second header 1024 to the fourth data lane 1008 and the sixth data lane 712. In FIG. 10, the data lanes 1002, 1004, 1006, 1008, 1010, 1012, 1014, 1016 in the partitions 1018, 1020 that have neither the largest nor the smallest size, the example variable length coding circuitry 606 assigns a third header 1026 to the second data lane 1004, the third data lane 1006, the fifth data lane 1010, and the eighth data lane 1016.

Furthermore, the example variable length coding circuitry 606 compresses the partitions 1018, 1020 by determining a size difference between the smallest data lanes 1002, 1014 and the largest data lanes 1008, 1012 in the respective partitions, appending respective portions of the largest data lanes 1008, 1012 to the smallest data lanes 1002, 1014, and recording slice sizes in the smallest data lanes 1002, 1014 indicative of byte sizes of the appended portions.

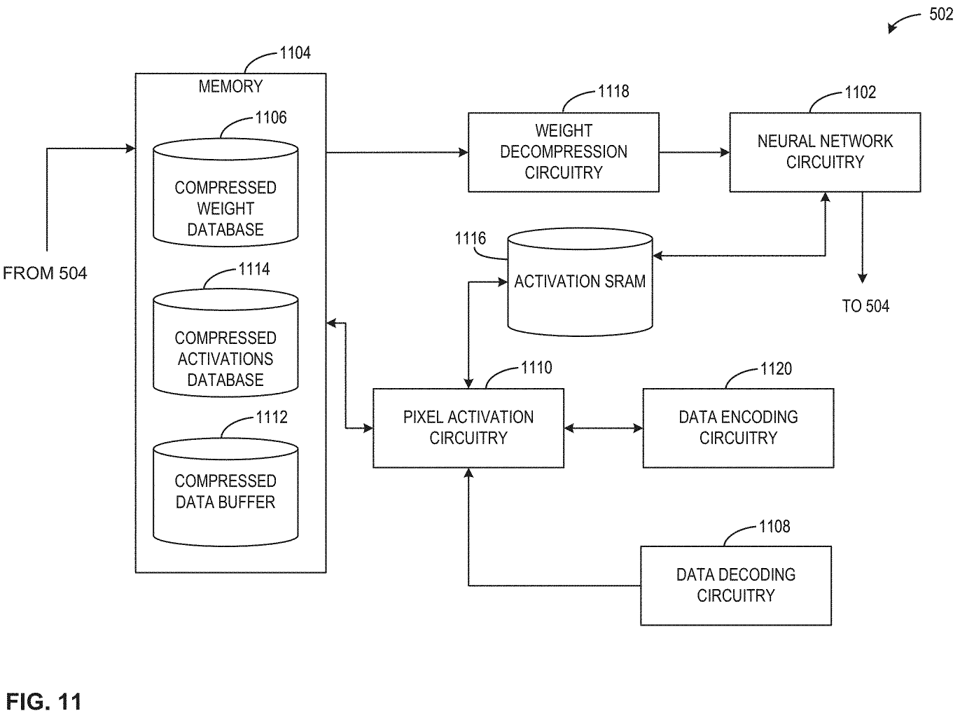

FIG. 11 is a block diagram of the example edge device 502 of the example system 500 of FIG. 5. In FIG. 11, the edge device 502 includes neural network circuitry 1102, a memory 1104, a compressed weight database 1106, data decoding circuitry 1108, pixel activation circuitry 1110, a compressed data buffer 1112, a compressed activations database 1114, an activation SRAM 1116, a weight decompression circuitry 1118, and data encoding circuitry 1120. In some examples, the neural network circuitry 1102, the memory 1104, the compressed weight database 1106, the data decoding circuitry 1108, the pixel activation circuitry 1110, the compressed data buffer 1112, the compressed activations database 1114, the activation SRAM 1116, the weight decompression circuitry 1118, and the data encoding circuitry 1120 of the edge device 502 are implemented via a system on a chip associated with the edge device 502.

In FIG. 11, the example neural network circuitry 1102 includes a neural network model that is trained via a training or learning algorithm and training data. Specifically, the neural network model processes the training data and generates an inference (e.g., a prediction). The inference is then compared to a target output and the result of the comparison is provided to the training or learning algorithm. In turn, the training or learning algorithm can modify connection weights in the neural network model based on the results of the comparison. In response to the neural network model being trained, the neural network circuitry 1102 transmits the neural network weights to the weight compression circuitry 504.

In FIG. 11, in response to compressing the neural network weights, the example weight compression circuitry 504 transmits the compressed weights (e.g., the fully compressed version 912 of the partitions 902, 904, 906, 908) to the memory 1104 of the edge device 502. Specifically, the example weight compression circuitry 504 loads the compressed weights onto the compressed weight database 1106. For example, the weight compression circuitry 504 can record the compressed weights in the compressed weight database 1106 during an installation process of the edge device 502. In FIG. 11, the example compressed weight database 1106 stores the compressed weights (e.g., the fully compressed version 912 of the partitions 902, 904, 906, 908).

In FIG. 11, during operation of the example edge device 502, the data decoding circuitry 1108 accesses compressed video data via ethernet or Peripheral Component Interconnect Express (PCI Express). Specifically, the video data serves as a first activation layer for the neural network model of the neural network circuitry 1102 when the video data is decompressed. In FIG. 11, the example data decoding circuitry 1108 decodes the accessed video data. In turn, the example data decoding circuitry 1108 transmits the decoded video data to the pixel activation circuitry 1110.

In FIG. 11, the example pixel activation circuitry 1110 records the compressed decoded video data in the compressed data buffer 1112 until the video data is to be processed by the neural network circuitry 1102. In FIG. 11, the example pixel activation circuitry 1110 obtains sparse/dense compressed activations via the compressed activations database 1114. Further, when the video data is to be processed by the neural network circuitry 1102, the example pixel activation circuitry 1110 extracts the compressed video data from the compressed data buffer 1112. In turn, the example pixel activation circuitry 1110 decompresses the video data, which becomes a first activation layer for the neural network model. In FIG. 11, the example pixel activation circuitry 1110 caches the first activation layer in the activation SRAM 1116.

In some examples, the pixel activation circuitry 1110 evicts a second activation layer (e.g., subsequent activation layers) from the activation SRAM 1116. In some examples, the pixel activation circuitry 1110 compresses the second activation layer. In turn, the example pixel activation circuitry 1110 stores the compressed second activation layer in the compressed activations database 1114 for subsequent utilization. As such, the example pixel activation circuitry 1110 can access the compressed second activation layer and decompress the same when the second activation layer is to be processed by the neural network model (e.g., with other video data).

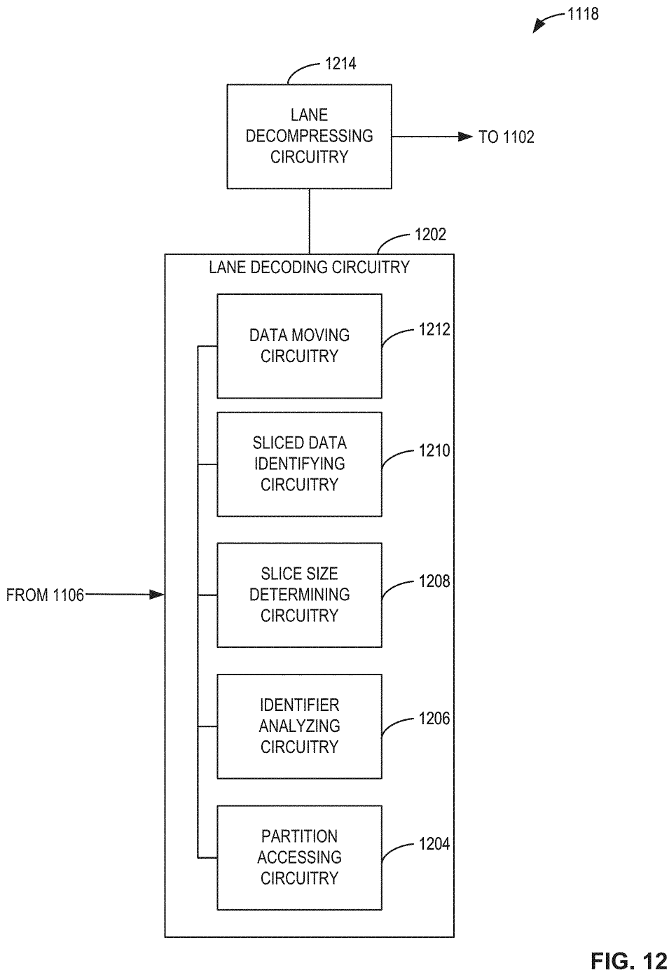

In FIG. 11, to process the video data, the example neural network circuitry 1102 access the first activation layer via the activation SRAM 1116. In FIG. 11, the example weight decompression circuitry 1118 accesses the compressed neural network weights via the compressed weight database 1106. In turn, the example weight decompression circuitry 1118 decompresses the neural network weights in parallel with the neural network circuitry 1102, as discussed in association with FIG. 12.

FIG. 12 illustrates the example weight decompression circuitry 1118 of the edge device 502. In FIG. 12, the example weight decompression circuitry 1118 includes lane decoding circuitry 1202 including partition accessing circuitry 1204, identifier analyzing circuitry 1206, slice size determining circuitry 1208, sliced data identifying circuitry 1210, and data moving circuitry 1212. In FIG. 12, the example weight decompression circuitry 1118 includes lane decompressing circuitry 1214.

In FIG. 12, the example lane decoding circuitry 1202 extracts compressed weights corresponding to the neural network weights associated with the neural network model of the neural network circuitry 1102 via the compressed weight database 1106. Specifically, the example partition accessing circuitry 1204 extracts the compressed partitions (e.g., the fully compressed version 912 of the partitions 902, 904, 906, 908) from the compressed weight database 1106.

In FIG. 12, the example identifier analyzing circuitry 1206 determines an identifier associated with data lanes (e.g., the data lanes 914, 916, 918, 920, 922, 924, 926, 928) of the compressed partitions. For example, the identifier analyzing circuitry 1206 can identify a value of a header byte (e.g., the header bytes 946, 948 of FIG. 9, the header bytes 1022, 1024, 1026 of FIG. 10) in the data lanes. Additionally or alternatively, the example identifier analyzing circuitry 1206 can identify the respective identifiers of the data lanes at any other position in the data lanes. For example, the identifier analyzing circuitry 1206 can identify respective footer bytes of the data lanes. In FIG. 12, the example identifier analyzing circuitry 1206 analyzes the identifiers in the respective data lanes to determine which of the data lanes includes appended data and which of the data lanes includes sliced data. For example, the identifier analyzing circuitry 1206 can determine one of the data lanes has appended data in response to identifying the data lane that has a first identifier, which is indicative of the data lane having the smallest original size in the partition. Accordingly, the example identifier analyzing circuitry 1206 can determine which one of the data lanes has sliced data in response to identifying the data lane that has a second identifier, which is indicative of the data lane having the smallest original size in the partition. In FIG. 12, the example identifier analyzing circuitry 1206 transmits a signal indicative of the data lanes having the appended data and the sliced data, respectively, to the slice size determining circuitry 1208. In some examples, the identifier analyzing circuitry 1206 removes the identifiers from each lane in response to identifying the data lanes having the smallest and largest original sizes.

In FIG. 12, the example slice size determining circuitry 1208 determines an amount of data that was cut from the data lane having the largest original size in the partition and appended to the data lane having the smallest original size in the partition during the compression of the partition performed by the variable length coding circuitry 606. Specifically, the example slice size determining circuitry 1208 determines the size of the appended data based on a value stored in a predetermined position in the data lane having the smallest original size. For example, to determine the size of the appended data, the slice size determining circuitry 1208 can identify a value stored in a predetermined amount of bytes after the header byte (e.g., slice sizes 950, 952, 954, 956). Additionally or alternatively, the example slice size determining circuitry 1208 can identify a value in front of a footer byte that identifies the data lane.

In some examples, the value that the slice size determining circuitry 1208 locates is the size of the appended data. In some examples, the value is an activation value indicative of the size of the appended data. For example, the value can be linked to the size of the appended data instead of indicating the size of the appended data directly. In such examples, the slice size determining circuitry 1208 performs a look up to correlate the action value to the size of the appended data. In FIG. 12, the example slice size determining circuitry 1208 transmits the size of the appended data to the sliced data identifying circuitry 1210. In some examples, the slice size determining circuitry 1208 removes bytes from the data lane that include that value indicative of the slice size in response to identifying the slice size.

In FIG. 12, the example sliced data identifying circuitry 1210 identifies (e.g., locates) the appended data in the originally smaller data lane. Specifically, the example sliced data identifying circuitry 1210 identifies the portion of the data in the data lane having the smaller original size that was sliced from the data lane having the larger original size. In FIG. 12, the example sliced data identifying circuitry 1210 locates the appended data within the originally smaller data lane. In FIG. 12, the example sliced data identifying circuitry 1210 identifies the appended data as the data at the end of the originally smaller data lane corresponding to the size of the appended data. Additionally or alternatively, the example sliced data identifying circuitry 1210 can locate the appended data at a beginning of the originally smaller data lane or adjacent the data indicative of the slice size in the originally smaller data lane. In turn, the example sliced data identifying circuitry 1210 transmits a signal indicative of the location and size of the appended data to the data moving circuitry 1212.

In FIG. 12, the example data moving circuitry 1212 moves the appended data from the originally smaller data lane back to the originally larger data lane to restore the data in the respective data lanes. For example, the data moving circuitry 1212 can move the appended data to a beginning or an end of the originally larger data lane. As such, a size difference between the originally smaller data lane and the originally larger data lane increases (e.g., is restored) in response to the data moving circuitry 1212 moving the appended data back to the originally larger data lane. In FIG. 12, the example data moving circuitry 1212 transmits the restored partition to the lane decompressing circuitry 1214.

In FIG. 12, the example lane decompressing circuitry 1214 decompresses the neural network weights in the partitions. In some examples, the lane decompressing circuitry 1214 removes the identifiers associated with the data lanes. In some examples, the lane decompressing circuitry 1214 removes the data indicative of the slice size in the data lane having the smallest original size. Further, the example lane decompressing circuitry 1214 can restore neural network weights that were pruned by the pruning circuitry 602 and/or compressed by the quantization circuitry 604. In turn, the example lane decompressing circuitry 1214 transmits the decompressed neural network weights to the neural network circuitry 1102. In FIG. 12, the example lane decompressing circuitry 1214 transmits the respective decompressed data lanes to the neural network circuitry 1102 in response to the data lane being decompressed. As such, the example neural network circuitry 1102 can utilize the weights in the decompressed data lane without having to wait for all of the data lanes to be decompressed. Moreover, the example lane decompressing circuitry 1214 includes multiple decompression engines that decompress data lanes in parallel to enable the neural network circuitry 1102 to operate with a high throughout.

Returning to FIG. 11, the neural network model of the example neural network circuitry 1102 processes the first activation layer using the neural network weights. As a result, the neural network model performs an inference based on the first activation layer. In some examples, the inference performed by the neural network model indicates detected and/or classified objects in the video data. In turn, the example neural network circuitry 1102 can highlight the detected and classified objects. In some examples, the neural network circuitry 1102 transmits the detected and classified objects to a display and/or otherwise indicates the results of the inference to a user. In some examples, the neural network circuitry 1102 forgets the neural network weights in response to performing the inference to save computing power in the edge device 502 and, thus, enable the edge device 502 to operate with an optimized or otherwise improved throughput.

In FIG. 11, the example neural network circuitry 1102 transmits the first activation layer to the activation SRAM 1116 in response to performing the inference. In FIG. 11, the example pixel activation circuitry 1110 extracts the first activation layer from the activation SRAM 1116 and transmits the first activation layer to the data encoding circuitry 1120. In FIG. 11, the example data encoding circuitry 1120 encodes the first activation layer. In turn, the example data encoding circuitry 1120 transmits the encoded first activation layer back to the pixel activation circuitry 1110. In FIG. 11, the example pixel activation circuitry 1110 compresses the encoded first activation layer. Accordingly, the example pixel activation circuitry 1110 can transmit the encoded and compressed first activation layer to the memory 1104 for storage. In some examples, the compressed activations database 1114 stores the encoded and compressed first activation layer.

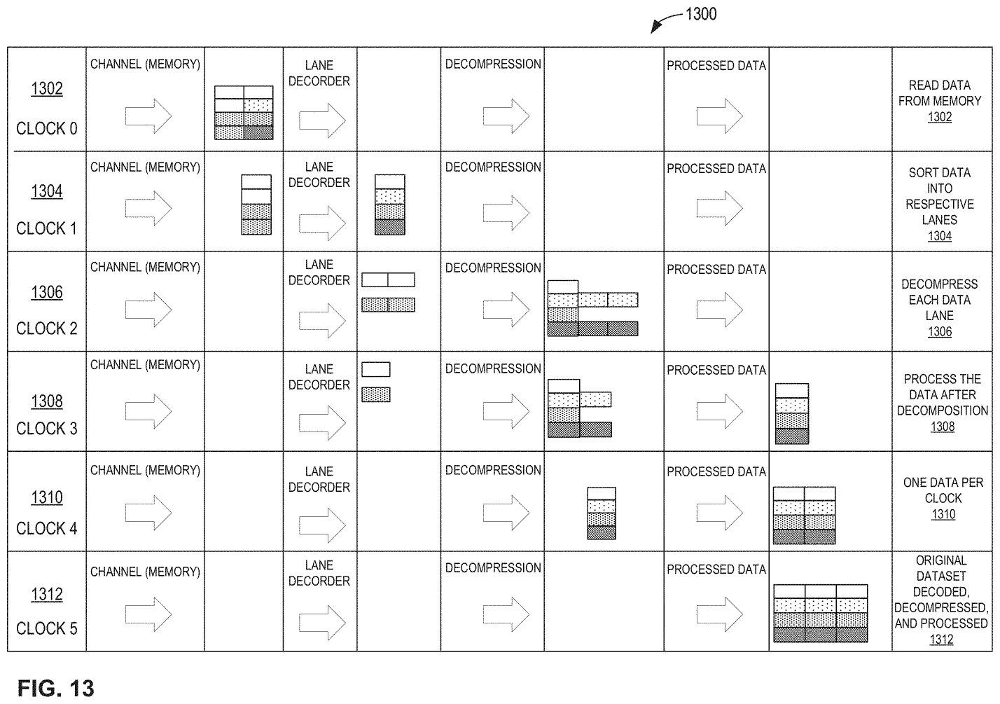

FIG. 13 illustrates the example decompression process 1300 performed by the edge device 502 of FIGS. 5 and/or 11. During a first step 1302 (“CLOCK 0”) of the process 1300, the lane decoding circuitry 1202 of the weight decompression circuitry 1118 reads data (e.g., compressed neural network weights) from the memory 1104. Specifically, the example partition accessing circuitry 1204 reads the data from the compressed weight database 1106.

During a second step 1304 (“CLOCK 1”) of the process 1300, the lane decoding circuitry 1202 sorts the data into the respective data lanes as the partition accessing circuitry 1204 continues to read the data from the compressed weight database 1106. For example, the identifier analyzing circuitry 1206 can identify the data lanes that include sliced data and appended data. Further, the example slice size determining circuitry 1208 can determine a size of the appended data. In turn, the sliced data identifying circuitry 1210 can determine a position of the appended data. Accordingly, the example data moving circuitry 1212 can move the appended data to the data lane including the sliced data to restore the data to the original lane associated therewith.

During a third step 1306 (“CLOCK 2”) of the process 1300, the example lane decompressing circuitry 1214 decompresses the sorted data in the data lanes as the lane decoding circuitry 1202 continues to sort the compressed data into the respective data lanes. During a fourth step 1308 (“CLOCK 3”) of the process, the example neural network circuitry 1102 processes the decompressed data (e.g., a first portion of the data) as the lane decompressing circuitry 1214 continues to decompress the sorted data (e.g., a second portion of the data). During a fifth step 1310 (“CLOCK 4”), the example neural network circuitry 1102 processes the decompressed data (e.g., the second portion of the data). By a sixth step 1312 (“CLOCK 5”) of the process 1300, the dataset, originally compressed by the example weight compression circuitry 504, has been decoded, decompressed, and processed.

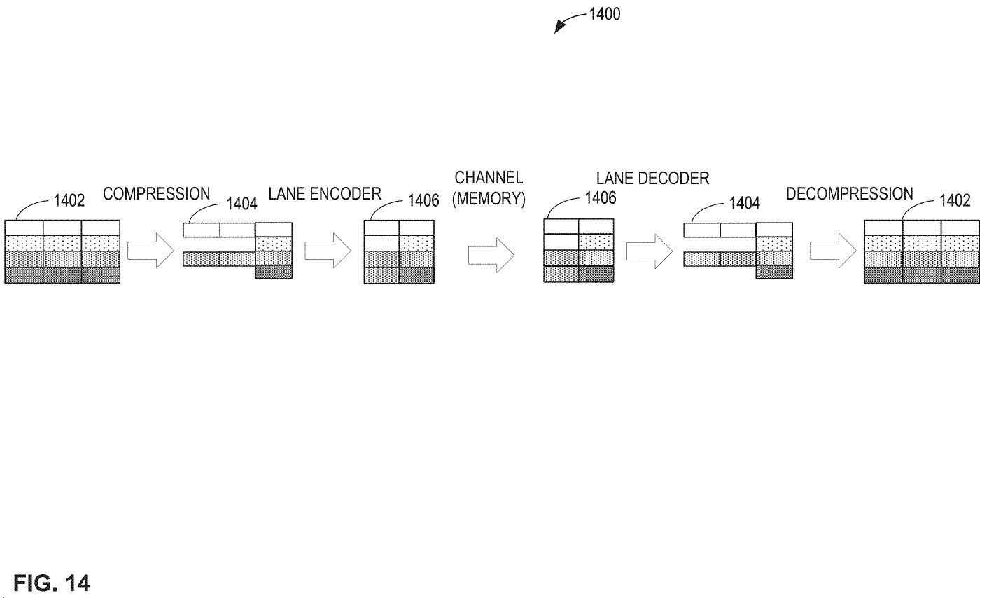

FIG. 14 illustrates an example high-level overview 1400 of the data compression and decompression process performed by the example system 500 of FIG. 5. In FIG. 14, a first portion of the example weight compression circuitry 504 accesses original (e.g., uncompressed) data 1402 (e.g., neural network weights) associated with the edge device 502. In FIG. 14, the example pruning circuitry 602 and the example quantization circuitry 604 convert the original data 1402 into partially compressed data 1404. In FIG. 14, the example variable length coding circuitry 606 encodes data from larger data lanes to smaller data lanes in the partially compressed data 1404 and, thus, converts the partially compressed data 1404 to fully compressed data 1406. In FIG. 14, the example variable length coding circuitry 606 stores the fully compressed data 1406 in the edge device 502. In FIG. 14, when the example neural network circuitry 1102 is to perform an inference, the example lane decoding circuitry 1202 of the weight decompression circuitry 1118 decodes portions of the fully compressed data 1406 that was moved from larger data lanes to smaller data lanes and, thus, converts the fully decompressed data 1406 back to the partially compressed data 1404. In FIG. 14, the example lane decompressing circuitry 1214 decompresses the partially compressed data 1404 to obtain the original data 1402, which the neural network circuitry 1102 can utilize to perform the inference.

FIG. 15 is a graph 1500 representative of example space savings that result from different compression techniques. In FIG. 15, the example graph 1500 includes theoretical data indicative of a theoretical compression limit, baseline data obtained from utilizing the baseline compression 400 described in association with FIG. 4, byte rotation data obtained from compression with byte rotation 450 as shown in FIG. 4, and lane encoding compression data obtained from the weight compression circuitry 504 of FIGS. 5 and 6.

In FIG. 15, the example graph 1500 presents compressed data associated with a first network (“RESNET50”) 1502, a second network (“SSD MOBILENET V1”) 1504, and a third network (“KITTY SEG”) 1506. In FIG. 15, the example first network 1502 is a classification network, which can determine identifiable groups or features represented in image data. In FIG. 15, the example second network 1504 is an object detection and classification network 1506, which can detect an object represented by image data and predict a class associated with the object. In FIG. 15, the example third network 1506 is a segmentation network, which determines segments into which image data is to be sorted.

In FIG. 15, neural network weights of the respective example networks 1502, 1504, 1506 are processed in the form of a first data type (“U8”) 1508 and a second data type (“FP 16”) 1510. For example, the first data type 1508 is an 8-bit integer data type and the second data type 1510 is a 16 bit floating-point data type. The second data type 1510 is capable of representing more precise, and a wider range of values than the first data type 1508. As such, more variability is present in the neural network weights using the second data type 1510 as a result of the weights encountering more rounding under the first data type 1508. Accordingly, data lanes of weights associated with the networks 1502, 1504, 1506 represented using the first data type 1508 have more correlation therein as the data lanes have a reduced number of values compared to data lanes of weights that are represented using the second data type 1510.

In FIG. 15, when the weights associated with the example networks 1502, 1504, 1506 are represented using the first data type 1508, each of the compression techniques result in comparable space savings for the weights associated with the networks 1502, 1504, 1506. Specifically, when the weights associated with the example networks 1502, 1504, 1506 are represented using the first data type 1508, the space savings that result from the compression techniques are relatively close to the theoretical limit because the higher correlation among the data in the data lanes representative of the weights results in optimal conditions for the baseline and rotation vector compression techniques.

In FIG. 15, when the weights associated with the example networks 1502, 1504, 1506 are represented using the second data type 1510, the lane encoding technique significantly outperforms the baseline and rotation vector compression techniques and is approximately equivalent to the theoretical limit. Specifically, the lane encoding compression technique disclosed herein does not rely on correlation in the data within the data lanes conversely to the rotation vector technique. Moreover, the lane encoding technique moves data from smaller data lanes to larger data lanes to avoid memory bubbles that the baseline compression technique encounters. As such, the lane encoding technique provides savings at or near a theoretical limit regardless of the data being compressed or the form in which the data is represented.

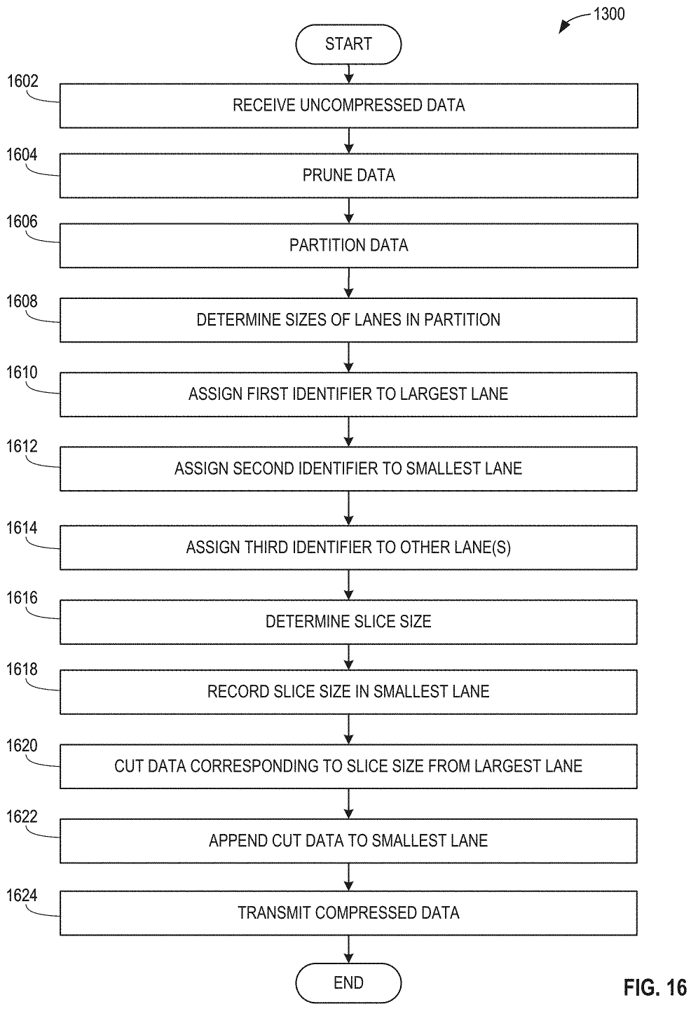

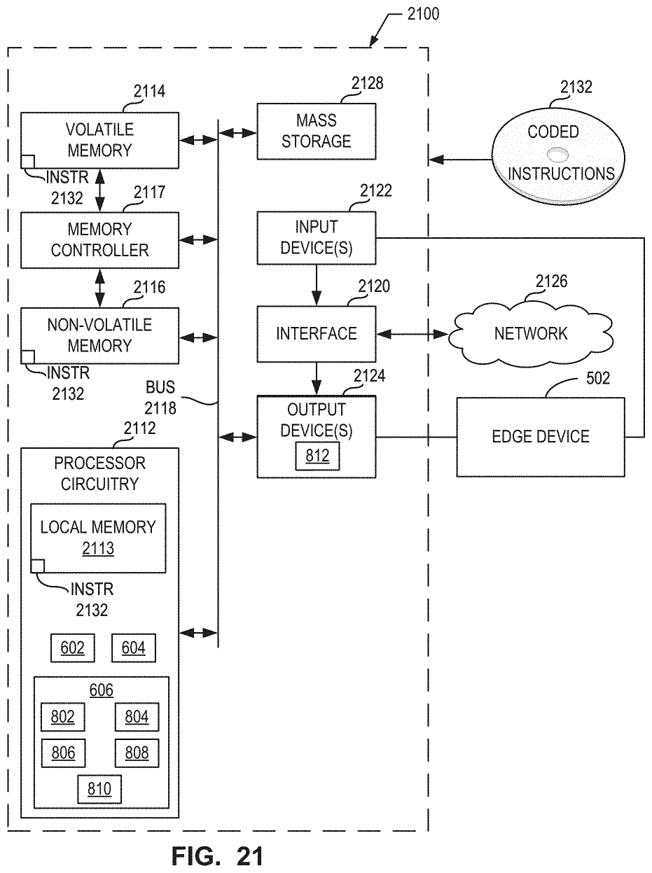

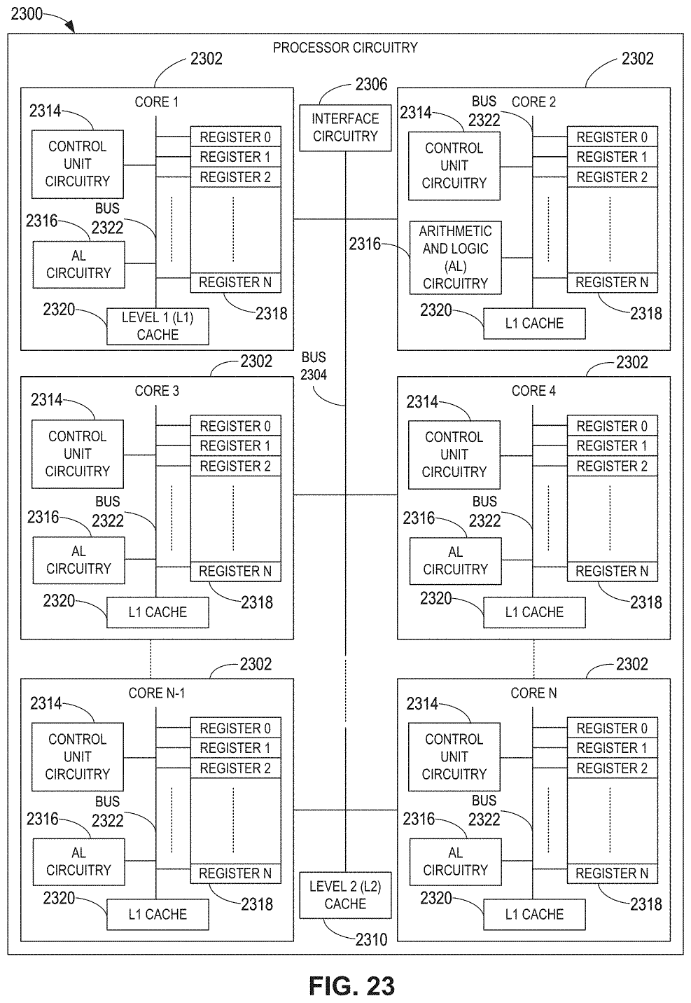

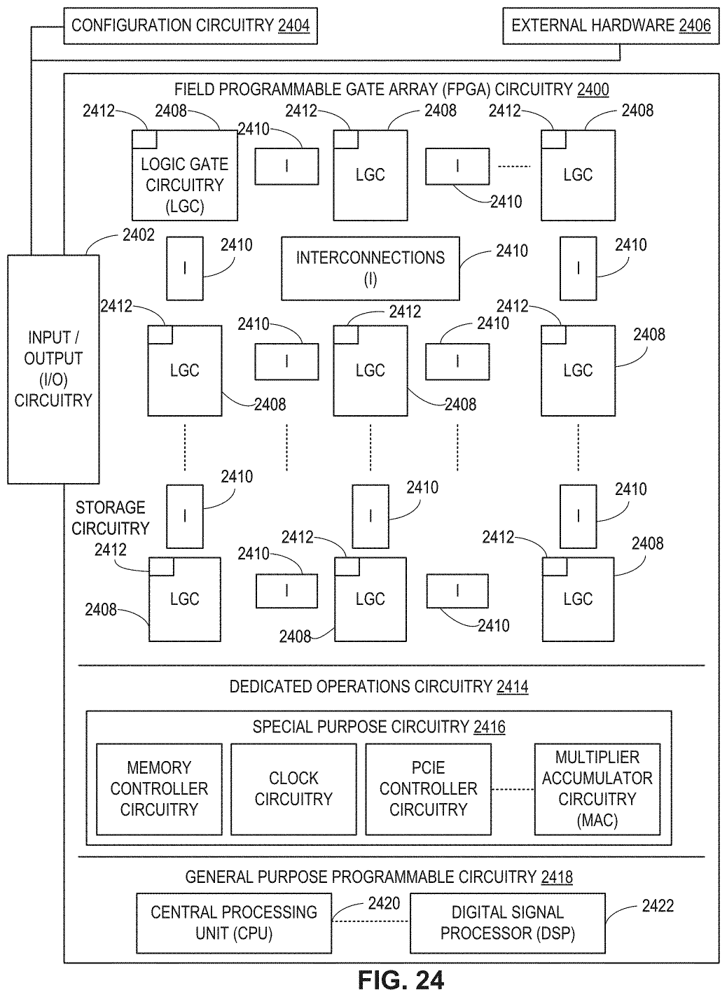

In some examples, the weight compression circuitry 504 includes means for determining sizes of data lanes. For example, the means for determining may be implemented by lane size computing circuitry 802. In some examples, the lane size computing circuitry 802 may be implemented by machine executable instructions such as that implemented by at least block 1608 of FIG. 16 executed by processor circuitry, which may be implemented by the example processor circuitry 2112 of FIG. 21, the example processor circuitry 2300 of FIG. 23, and/or the example Field Programmable Gate Array (FPGA) circuitry 2400 of FIG. 24. In other examples, the lane size computing circuitry 802 is implemented by other hardware logic circuitry, hardware implemented state machines, and/or any other combination of hardware, software, and/or firmware. For example, the lane size computing circuitry 802 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the weight compression circuitry 504 includes means for identifying data lanes. For example, the means for identifying data lanes may be implemented by lane identifying circuitry 804. In some examples, the lane identifying circuitry 804 may be implemented by machine executable instructions such as that implemented by at least blocks 1610, 1612, 1614 of FIG. 16 executed by processor circuitry, which may be implemented by the example processor circuitry 2112 of FIG. 21, the example processor circuitry 2300 of FIG. 23, and/or the example Field Programmable Gate Array (FPGA) circuitry 2400 of FIG. 24. In other examples, the lane identifying circuitry 804 is implemented by other hardware logic circuitry, hardware implemented state machines, and/or any other combination of hardware, software, and/or firmware. For example, the lane identifying circuitry 804 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the weight compression circuitry 504 includes means for assigning identifiers to data lanes. For example, the means for assigning identifiers to data lanes may be implemented by lane identifying circuitry 804. In some examples, the lane identifying circuitry 804 may be implemented by machine executable instructions such as that implemented by at least blocks 1610, 1612, 1614 of FIG. 16 executed by processor circuitry, which may be implemented by the example processor circuitry 2112 of FIG. 21, the example processor circuitry 2300 of FIG. 23, and/or the example Field Programmable Gate Array (FPGA) circuitry 2400 of FIG. 24. In other examples, the lane identifying circuitry 804 is implemented by other hardware logic circuitry, hardware implemented state machines, and/or any other combination of hardware, software, and/or firmware. For example, the lane identifying circuitry 804 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the weight compression circuitry 504 includes means for determining a slice size. For example, the means for determining a slice size may be implemented by slice size computing circuitry 806. In some examples, the slice size computing circuitry 806 may be implemented by machine executable instructions such as that implemented by at least block 1616 of FIG. 16 executed by processor circuitry, which may be implemented by the example processor circuitry 2112 of FIG. 21, the example processor circuitry 2300 of FIG. 23, and/or the example Field Programmable Gate Array (FPGA) circuitry 2400 of FIG. 24. In other examples, the slice size computing circuitry 806 is implemented by other hardware logic circuitry, hardware implemented state machines, and/or any other combination of hardware, software, and/or firmware. For example, the slice size computing circuitry 806 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the weight compression circuitry 504 includes means for recording a slice size or a value corresponding to a slice size in a data lane. For example, the means for recording may be implemented by slice size computing circuitry 806. In some examples, the slice size computing circuitry 806 may be implemented by machine executable instructions such as that implemented by at least block 1618 of FIG. 16 executed by processor circuitry, which may be implemented by the example processor circuitry 2112 of FIG. 21, the example processor circuitry 2300 of FIG. 23, and/or the example Field Programmable Gate Array (FPGA) circuitry 2400 of FIG. 24. In other examples, the slice size computing circuitry 806 is implemented by other hardware logic circuitry, hardware implemented state machines, and/or any other combination of hardware, software, and/or firmware. For example, the slice size computing circuitry 806 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the weight compression circuitry 504 includes means for cutting a portion of data. For example, the means for cutting may be implemented by data slicing circuitry 808. In some examples, the data slicing circuitry 808 may be implemented by machine executable instructions such as that implemented by at least block 1620 of FIG. 16 executed by processor circuitry, which may be implemented by the example processor circuitry 2112 of FIG. 21, the example processor circuitry 2300 of FIG. 23, and/or the example Field Programmable Gate Array (FPGA) circuitry 2400 of FIG. 24. In other examples, the data slicing circuitry 808 is implemented by other hardware logic circuitry, hardware implemented state machines, and/or any other combination of hardware, software, and/or firmware. For example, the data slicing circuitry 808 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the weight compression circuitry 504 includes means for appending a portion of data to a data lane. For example, the means for appending may be implemented by data appending circuitry 810. In some examples, the data appending circuitry 810 may be implemented by machine executable instructions such as that implemented by at least block 1622 of FIG. 16 executed by processor circuitry, which may be implemented by the example processor circuitry 2112 of FIG. 21, the example processor circuitry 2300 of FIG. 23, and/or the example Field Programmable Gate Array (FPGA) circuitry 2400 of FIG. 24. In other examples, the data appending circuitry 810 is implemented by other hardware logic circuitry, hardware implemented state machines, and/or any other combination of hardware, software, and/or firmware. For example, the data appending circuitry 810 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

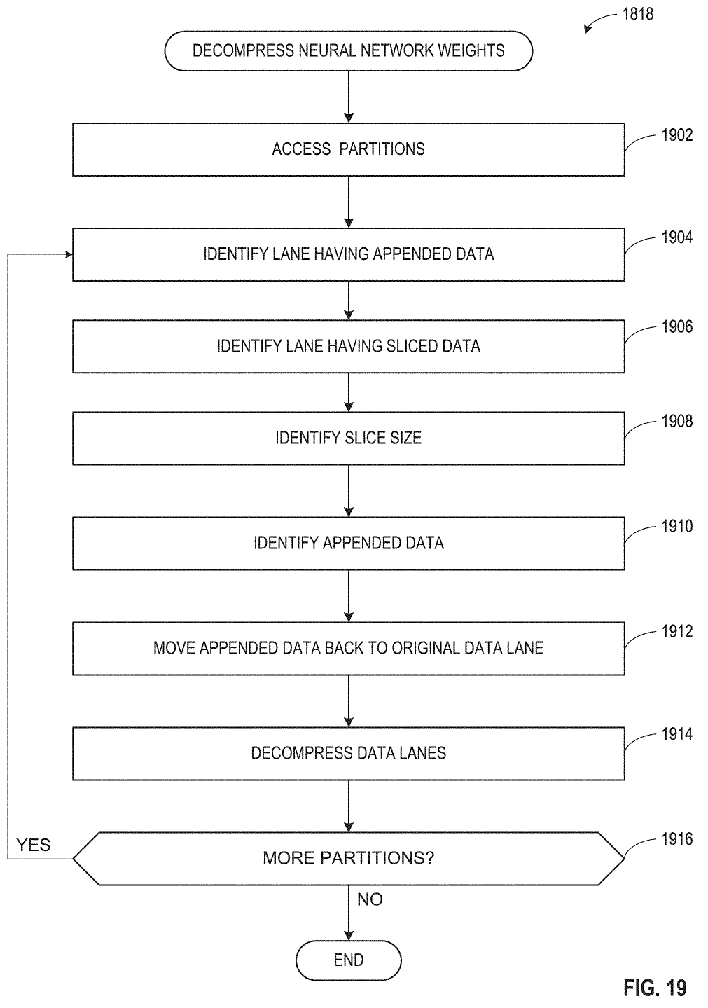

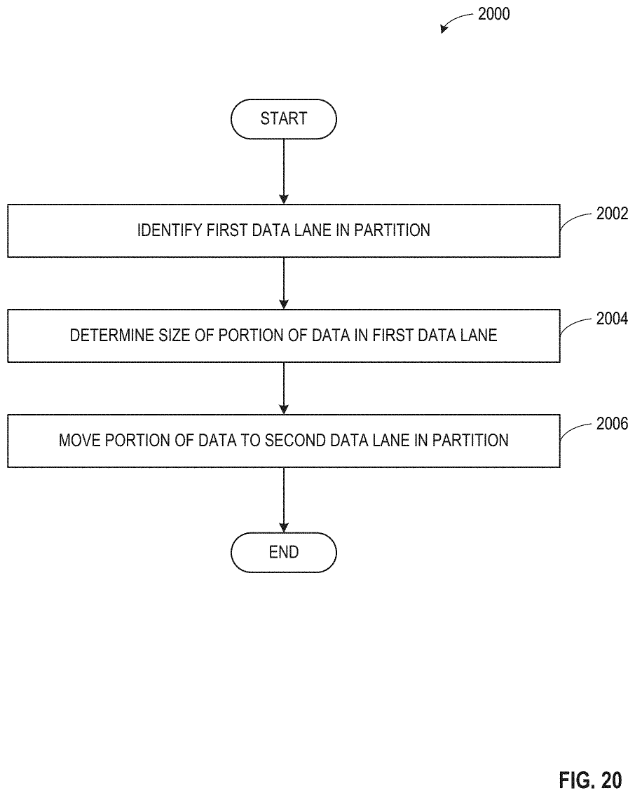

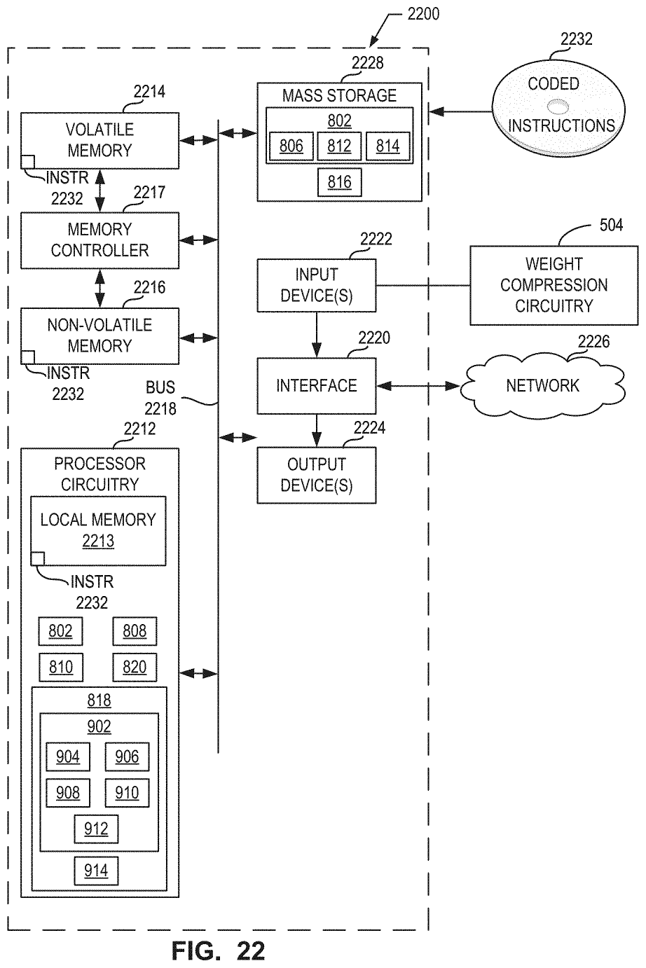

In some examples, the weight decompression circuitry 1118 includes means for identifying a first data lane in a partition based on a first portion of the first data lane. For example, the means for identifying may be implemented by identifier analyzing circuitry 1206. In some examples, the identifier analyzing circuitry 1206 may be implemented by machine executable instructions such as that implemented by at least blocks 1904, 1906, 2002 of FIGS. 19 and 20 executed by processor circuitry, which may be implemented by the example processor circuitry 2212 of FIG. 22, the example processor circuitry 2300 of FIG. 23, and/or the example Field Programmable Gate Array (FPGA) circuitry 2400 of FIG. 24. In other examples, the identifier analyzing circuitry 1206 is implemented by other hardware logic circuitry, hardware implemented state machines, and/or any other combination of hardware, software, and/or firmware. For example, the identifier analyzing circuitry 1206 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the weight decompression circuitry 1118 includes means for determining a size of a second portion of the first data based on a third portion of the first data. For example, the means for determining may be implemented by the slice size determining circuitry 1208. In some examples, the slice size determining circuitry 1208 may be implemented by machine executable instructions such as that implemented by at least blocks 1908, 2004 of FIGS. 19 and 20 executed by processor circuitry, which may be implemented by the example processor circuitry 2212 of FIG. 22, the example processor circuitry 2300 of FIG. 23, and/or the example Field Programmable Gate Array (FPGA) circuitry 2400 of FIG. 24. In other examples, the slice size determining circuitry 1208 is implemented by other hardware logic circuitry, hardware implemented state machines, and/or any other combination of hardware, software, and/or firmware. For example, the slice size determining circuitry 1208 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the weight decompression circuitry 1118 includes means for moving the second portion of the first data to a second data lane in the partition. For example, the means for moving may be implemented by the data moving circuitry 1212. In some examples, the data moving circuitry 1212 may be implemented by machine executable instructions such as that implemented by at least blocks 1912, 2006 of FIGS. 19 and 20 executed by processor circuitry, which may be implemented by the example processor circuitry 2212 of FIG. 22, the example processor circuitry 2300 of FIG. 23, and/or the example Field Programmable Gate Array (FPGA) circuitry 2400 of FIG. 24. In other examples, the data moving circuitry 1212 is implemented by other hardware logic circuitry, hardware implemented state machines, and/or any other combination of hardware, software, and/or firmware. For example, the data moving circuitry 1212 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

In some examples, the weight decompression circuitry 1118 includes means for locating the second portion of the first data at an end of the first data lane based on the size. For example, the means for locating may be implemented by the sliced data identifying circuitry 1210. In some examples, the sliced data identifying circuitry 1210 may be implemented by machine executable instructions such as that implemented by at least block 1910 of FIG. 19 executed by processor circuitry, which may be implemented by the example processor circuitry 2212 of FIG. 22, the example processor circuitry 2300 of FIG. 23, and/or the example Field Programmable Gate Array (FPGA) circuitry 2400 of FIG. 24. In other examples, the sliced data identifying circuitry 1210 is implemented by other hardware logic circuitry, hardware implemented state machines, and/or any other combination of hardware, software, and/or firmware. For example, the sliced data identifying circuitry 1210 may be implemented by at least one or more hardware circuits (e.g., processor circuitry, discrete and/or integrated analog and/or digital circuitry, an FPGA, an Application Specific Integrated Circuit (ASIC), a comparator, an operational-amplifier (op-amp), a logic circuit, etc.) structured to perform the corresponding operation without executing software or firmware, but other structures are likewise appropriate.

While an example manner of implementing the weight compression circuitry 504 of FIG. 5 is illustrated in FIGS. 6 and 8, one or more of the elements, processes, and/or devices illustrated in FIGS. 6 and 8 may be combined, divided, re-arranged, omitted, eliminated, and/or implemented in any other way. Further, the example pruning circuitry 602, the example quantization circuitry 604, the example variable length coding circuitry 606, the example lane size computing circuitry 802, the example lane identifying circuitry 804, the example slice size computing circuitry 806, the example data slicing circuitry 808, the example data appending circuitry 810, the example compressed weight transmitter 812 and/or, more generally, the example weight compression circuitry 504 of FIGS. 5, 6, and 8, may be implemented by hardware alone or by hardware in combination with software and/or firmware. Thus, for example, any of the example pruning circuitry 602, the example quantization circuitry 604, the example variable length coding circuitry 606, the example lane size computing circuitry 802, the example lane identifying circuitry 804, the example slice size computing circuitry 806, the example data slicing circuitry 808, the example data appending circuitry 810, the example compressed weight transmitter 812, and/or, more generally, the example weight compression circuitry 504, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example weight compression circuitry 504 of FIGS. 5, 6, and 8 may include one or more elements, processes, and/or devices in addition to, or instead of, those illustrated in FIGS. 5, 6, and/or 8, and/or may include more than one of any or all of the illustrated elements, processes, and devices.

While an example manner of implementing the edge device 502 of FIG. 5 is illustrated in FIGS. 11 and 12, one or more of the elements, processes, and/or devices illustrated in FIGS. 11 and 12 may be combined, divided, re-arranged, omitted, eliminated, and/or implemented in any other way. Further, the example neural network circuitry 1102, the example memory 1104, the example compressed weight database 1106, the example data decoding circuitry 1108, the example pixel activation circuitry 1110, the example compressed data buffer 1112, the example compressed activations database 1114, the example activation SRAM 1116, the example decompression circuitry 818, the example data encoding circuitry 1120, the example lane decoding circuitry 1202, the example partition accessing circuitry 1204, the example identifier analyzing circuitry 1206, the example slice size determining circuitry 1208, the example sliced data identifying circuitry 1210, the example data moving circuitry 1212, the example lane decompressing circuitry 1214, and/or, more generally, the example edge device 502 of FIGS. 5, 11, and/or 12, may be implemented by hardware alone or by hardware in combination with software and/or firmware. Thus, for example, any of the example neural network circuitry 1102, the example memory 1104, the example compressed weight database 1106, the example data decoding circuitry 1108, the example pixel activation circuitry 1110, the example compressed data buffer 1112, the example compressed activations database 1114, the example activation SRAM 1116, the example decompression circuitry 818, the example data encoding circuitry 1120, the example lane decoding circuitry 1202, the example partition accessing circuitry 1204, the example identifier analyzing circuitry 1206, the example slice size determining circuitry 1208, the example sliced data identifying circuitry 1210, the example data moving circuitry 1212, the example lane decompressing circuitry 1214, and/or, more generally, the example edge device 502, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example edge device 502 of FIGS. 5, 11, and/or 12 may include one or more elements, processes, and/or devices in addition to, or instead of, those illustrated in FIGS. 5, 11, and/or 12, and/or may include more than one of any or all of the illustrated elements, processes, and devices.

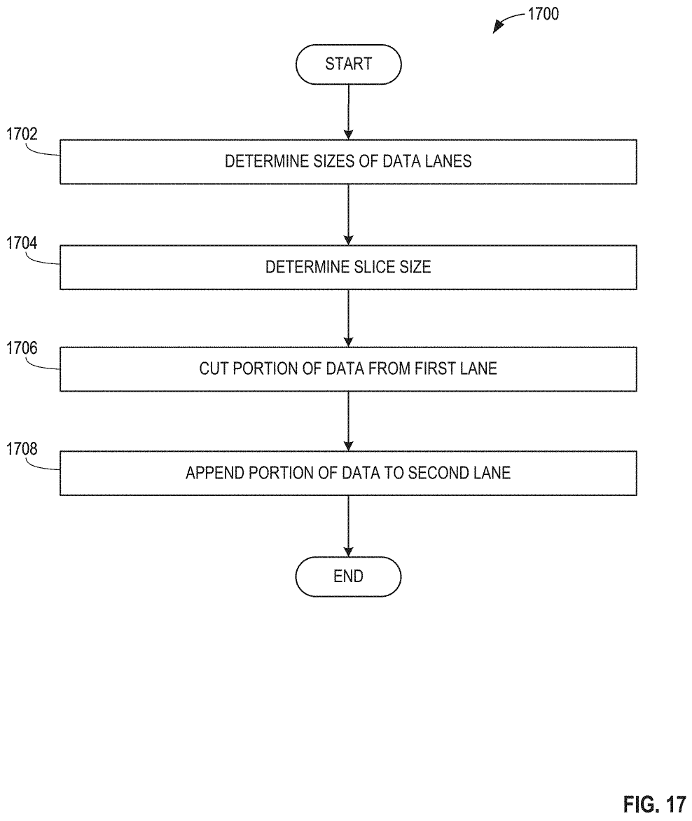

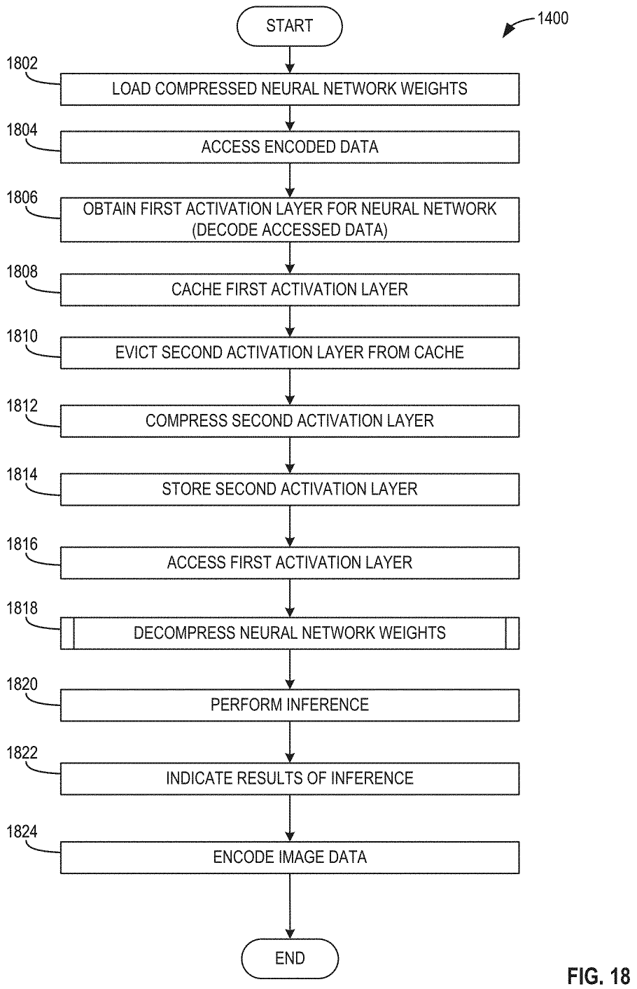

Flowcharts representative of example hardware logic circuitry, machine readable instructions, hardware implemented state machines, and/or any combination thereof for implementing the weight compression circuitry 504 of FIGS. 5, 6, and 8 is shown in FIGS. 16 and 17. Flowcharts representative of example hardware logic circuitry, machine readable instructions, hardware implemented state machines, and/or any combination thereof for implementing the edge device 502 of FIGS. 5, 11, and 12 are shown in FIGS. 18, 19, and 20. The machine readable instructions of FIGS. 16 and 17 may be one or more executable programs or portion(s) of an executable program for execution by processor circuitry, such as the processor circuitry 2112 shown in the example processor platform 2100 discussed below in connection with FIG. 21 and/or the example processor circuitry discussed below in connection with FIGS. 23 and/or 24. The machine readable instructions of FIGS. 18, 19, and 20 may be one or more executable programs or portion(s) of an executable program for execution by processor circuitry, such as the processor circuitry 2212 shown in the example processor platform 2200 discussed below in connection with FIG. 22 and/or the example processor circuitry discussed below in connection with FIGS. 23 and/or 24. The programs may be embodied in software stored on one or more non-transitory computer readable storage media such as a CD, a floppy disk, a hard disk drive (HDD), a DVD, a Blu-ray disk, a volatile memory (e.g., Random Access Memory (RAM) of any type, etc.), or a non-volatile memory (e.g., FLASH memory, an HDD, etc.) associated with processor circuitry located in one or more hardware devices, but the entireties of the programs and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN) gateway that may facilitate communication between a server and an endpoint client hardware device). Similarly, the non-transitory computer readable storage media may include one or more mediums located in one or more hardware devices. Further, although the example programs are described with reference to the flowcharts illustrated in FIGS. 16, 17, 18, 19, and/or 20, many other methods of implementing the example weight compression circuitry 504 and/or the edge device 502 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU), etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 16, 17, 18, 19, and 20 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium and non-transitory computer readable storage medium is expressly defined to include any type of computer readable storage device and/or storage disk and to exclude propagating signals and to exclude transmission media.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 16 is a flowchart representative of example machine readable instructions and/or example operations 1600 that may be executed and/or instantiated by processor circuitry to implement the example weight compression circuitry 504 (FIGS. 5 and 6) to compress data, such as weights associated with a neural network. The machine readable instructions and/or operations 1600 of FIG. 16 begin at block 1602, at which the example weight compression circuitry 504 (FIGS. 5 and 6) receives uncompressed data. For example, the pruning circuitry 602 (FIG. 6) can receive uncompressed neural network weights, as shown in FIG. 6.

At block 1604, the example weight compression circuitry 504 prunes the received data. For example, the pruning circuitry 602 can prune the data in response to receiving the uncompressed data at block 1302. As such, the pruning circuitry 602 converts the uncompressed data to partially compressed data by removing weights below a certain threshold.

At block 1606, the example weight compression circuitry 504 partitions the data. For example, the quantization circuitry 604 (FIG. 6) partitions the data to further compress the partially compressed data. In some examples, the quantization circuitry 604 can divide the data into partitions based on ranges of values in respective segments of the data. Further, the example quantization circuitry 604 can update floating-point values in the data to lower bit width values to reduce a bit size of the values and, thus, a memory bandwidth that the data utilizes.

At block 1608, the example weight compression circuitry 504 determines sizes of data lanes in the partitions. For example, the variable length coding circuitry 606 (FIG. 6) can determine the sizes of the data lanes in the partitions. In some examples, the lane size computing circuitry 802 (FIG. 8) computes the sizes of the data lanes in bytes.

At block 1610, the example weight compression circuitry 504 assigns a first identifier to a largest data lane in the partition. For example, the variable length coding circuitry 606 can assign the first identifier to the largest data lane in the partition in response to determining the sizes of all the data lanes in the partition. In some examples, the lane identifying circuitry 804 (FIG. 8) assigns a first header byte or a first footer byte to the largest lane in the partition to identify the largest lane.

At block 1612, the example weight compression circuitry 504 assigns a second identifier to a smallest data lane in the partition. For example, the variable length coding circuitry 606 can assign the second identifier to the smallest data lane in the partition in response to determining the sizes of all the data lanes in the partition. In some examples, the lane identifying circuitry 804 assigns a second header byte different from the first header byte or a second footer byte different from the first footer byte to the smallest data lane in the partition to identify the smallest data lane and distinguish the smallest data lane from the largest data lane.

At block 1614, the example weight compression circuitry 504 assigns a third identifier to any other data lane(s) in the partition. For example, the variable length coding circuitry 606 can assign the third identifier to the data lanes having sizes between the largest data lane size and the smallest data lane size in response to determining the sizes of all the data lanes in the partition. In some examples, the lane identifying circuitry 804 assigns a third header byte different from the first and second header bytes or a third footer byte different from the first and second footer bytes byte to the largest data lane in the partition to identify the largest data lane.

At block 1616, the example weight compression circuitry 504 determines a slice size of data to be moved from the largest data lane to the smallest data lane. For example, the variable length coding circuitry 606 determines the slice size based on a size difference between the largest data lane and the smallest data lane. In some examples, the slice size computing circuitry 806 computes the slice size based on the size difference between the largest data lane and the smallest data lane.

At block 1618, the example weight compression circuitry 504 records the slice size (e.g., a value indicative of the slice size) in the smallest data lane. For example, the variable length coding circuitry 606 writes the slice size in a predetermined position in the smallest data lane. In some examples, the slice size computing circuitry 806 inserts the slice size in the smallest data lane in a predetermined number of bytes (e.g., 2 bytes, 4 bytes, 6 bytes, etc.) adjacent to the identifier in the smallest data lane.

At block 1620, the example weight compression circuitry 504 cuts data corresponding to the slice size from the largest data lane. For example, the variable length coding circuitry 606 cuts the data corresponding to the slice size from a predetermined position in the largest data lane. In some examples, the data slicing circuitry 808 (FIG. 8) cuts the data corresponding to the slice size from a first end of the data lane or a second end of the data lane opposite the first end. In some examples, the data slicing circuitry 808 cuts the data corresponding to the slice size from another location in the largest data lane, such as a middle of the largest data lane.

At block 1622, the example weight compression circuitry 504 appends the cut data to the smallest data lane. For example, the variable length coding circuitry 606 moves the data cut from the largest data lane to a predetermined position in the smallest data lane. In some examples, the data appending circuitry 810 (FIG. 8) appends the cut data to an end of the smallest data lane. In some examples, the data appending circuitry 810 appends the cut data to another location in the smallest data lane, such as in a location adjacent to bytes including the slice size.

At block 1624, the example weight compression circuitry 504 transmits the compressed data. For example, the variable length coding circuitry 606 can transmit the compressed data to a source from which the uncompressed data was received in block 1602. In some examples, the compressed weight transmitter 812 (FIG. 8) transmits the data lanes including the compressed data to the source associated with the uncompressed data.

FIG. 17 is a second flowchart representative of example machine readable instructions and/or example operations 1700 that may be executed and/or instantiated by processor circuitry to implement the example weight compression circuitry 504 of FIGS. 5 and 6 to compress data, such as weights associated with a neural network. The machine readable instructions and/or operations 1700 of FIG. 17 begin at block 1702, at which the example weight compression circuitry (FIGS. 5 and 6) determines sizes of data lanes. For example, the variable length coding circuitry 606 (FIG. 6) can determine the sizes of the data lanes in a partition. In some examples, the lane size computing circuitry 802 (FIG. 8) computes the sizes of the data lanes in bytes.

At block 1704, the example weight compression circuitry 504 determines a slice size. For example, the variable length coding circuitry 606 can determine the slice size based on a size difference between a first data lane and a second data lane of the data lanes in the partition. Specifically, the first data lane can include first data, and the second data lane can include second data of a smaller size than the first data. In some examples, the slice size computing circuitry 806 (FIG. 8) determines the slice size.

At block 1706, the example weight compression circuitry 504 cuts a portion of the first data from the first data lane. For example, the variable length coding circuitry 606 can cut the portion of the first data from the first data lane based on the slice size. In some examples, the data slicing circuitry 808 (FIG. 8) cuts the portion of the first data from the first data lane.

At block 1708, the example weight compression circuitry 504 appends the portion of the first data to the second data lane. For example, the variable length coding circuitry 606 can append the portion of the first data to an end of the second data lane. In some examples, the data appending circuitry 810 (FIG. 8) appends the portion of the first data to the second data lane.

FIG. 18 is a flowchart representative of example machine readable instructions and/or example operations 1800 that may be executed and/or instantiated by processor circuitry to implement the edge device 502 (FIGS. 5 and 11) to highlight detected and/or classified objects in data, such as image data. The machine readable instructions and/or operations 1800 of FIG. 18 begin at block 1802, at which the example edge device 502 loads compressed neural network weights. For example, the memory 1104 (FIG. 11) can load the compressed neural network weights associated with the neural network circuitry 1102 (FIG. 11). In some examples, the compressed weight database 1106 (FIG. 11) stores the compressed neural network weights. In some examples, the neural network circuitry 1102 transmits a signal indicative of the weights to the weight compression circuitry 504 (FIG. 5) for use in compressing data (e.g., the data 1402 of FIG. 14). In some examples, the neural network weights are loaded onto the weight compression circuitry 504 for use in compressing data offline.

At block 1804, the example edge device 502 accesses encoded data. For example, the data decoding circuitry 1108 can access encoded image data via an Ethernet network connection or a PCI Express bus. In some examples, the data decoding circuitry 1108 is coupled to a camera that captures the image data.

At block 1806, the example edge device 502 obtains a first activation layer for a neural network model. For example, the data decoding circuitry 1108 can decode the image data. Further, the example pixel activation circuitry 1110 (FIG. 11) can determine the first activation layer based on the image data. In some examples, the pixel activation circuitry 1110 stores the image data in the compressed data buffer 1112 (FIG. 11) until the image data is to be processed. In some examples, the pixel activation circuitry 1110 determines the first activation layer associated with the pixels based on activations stored in the compressed activations database 1114 (FIG. 11).

At block 1808, the example edge device 502 caches the first activation layer. For example, the pixel activation circuitry 1110 can cache the first activation layer in the activation SRAM 1116 (FIG. 11). Accordingly, the activation SRAM 1116 can hold the first activation layer until the neural network circuitry 1102 processes the first activation layer.

At block 1810, the example edge device 502 evicts a second activation layer. For example, the pixel activation circuitry 1110 can evict the second activation layer (e.g., an activation layer previously processed by the neural network circuitry 1102) from the activation SRAM 1116.

At block 1812, the example edge device 502 compresses the second activation layer. For example, the pixel activation circuitry 1110 can compress the second activation layer.

At block 1814, the example edge device 502 stores the second activation layer. For example, the pixel activation circuitry 1110 stores the second activation layer in the memory 1104. In some examples, the pixel activation circuitry 1110 stores the second activation layer in the compressed activations database 1114 for later usage.

At block 1816, the example edge device 502 accesses the first activation layer. For example, when the neural network circuitry 1102 is to perform an inference based on the image data, the neural network circuitry 1102 can access the first activation layer via the activation SRAM 1116.

At block 1818, the example edge device 502 decompresses the compressed neural network weights. For example, the weight decompression circuitry 1118 can access the compressed weights stored in the memory 1104. In some examples, the weight decompression circuitry 1118 obtains the compressed weights via the compressed weight database 1106. Example instructions that may be executed to implement the weight decompression circuitry 1118 to decompress the compressed weights are discussed below in association with FIGS. 19 and/or 20.

At block 1820, the example edge device 502 performs an inference based on the image data. For example, the neural network circuitry 1102 can perform an inference or prediction based on the image data and the neural network weights associated therewith. In some examples, the neural network circuitry 1102 processes the image data in parallel with the process of block 1818 occurring. That is, the neural network circuitry 1102 can process the image data using a first portion of the neural network weights as a second portion of the neural network weights are being decompressed by the weight decompression circuitry 1118. Accordingly, the neural network circuitry 1102 generates the inference in response to processing the image data with the second portion of the neural network weights. In some examples, the neural network circuitry 1102 highlights detected and/or classified objects in the image data as a result of the inference.

At block 1822, the example edge device 502 indicates the result of the inference. For example, the neural network circuitry 1102 can transmit the result to the activation SRAM 1116. In some examples, the neural network circuitry 1102 transmits the results to an end node, such as one or more of the end points 160 (FIG. 1).

At block 1824, the example edge device 502 encodes the image data. For example, the pixel activation circuitry 1110 (FIG. 11) can re-access the image data in the activation SRAM 1116 in response to the neural network circuitry 1102 performing the inference. Further, the example pixel activation circuitry 1110 can transmit the image data to the data encoding circuitry 1120 (FIG. 11). In turn, the example data encoding circuitry 1120 can encode and/or compress the image data. In some examples, the data encoding circuitry 1120 transmits the encoded image data to the pixel activation circuitry 1110, which stores the encoded image data in the memory 1104. In some examples, the pixel activation circuitry 1110 stores the encoded image data in the compressed data buffer 1112 (FIG. 11).

FIG. 19 is a first flowchart representative of example machine readable instructions and/or example operations 1818 that may be executed and/or instantiated by processor circuitry to implement block 1818 of FIG. 18 to decompress neural network weights previously compressed in accordance with the example operations 1600 of FIG. 16. The machine readable instructions and/or operations 1818 of FIG. 18 begin at block 1902, at which the weight decompression circuitry 1118 (FIG. 11) accesses partitions of the compressed neural network weights. For example, the lane decoding circuitry 1202 (FIG. 12) can access the partitions including the compressed neural network weights. In some examples, the partition accessing circuitry 1204 (FIG. 12) accesses the partitions.

At block 1904, the example weight decompression circuitry 1118 identifies a data lane having appended data. For example, the lane decoding circuitry 1202 can determine which of the data lanes in the partitions includes appended data based on identifiers associated with the data lanes. That is, the lane decoding circuitry 1202 can search for a first identifier indicative of the data lane having a smallest original (e.g., uncompressed) size of all the data lanes in the partition, which is indicative of the data lane having the appended data when compressed. In some examples, the identifier analyzing circuitry 1206 (FIG. 12) analyzes a byte (e.g., a header byte, a footer byte, etc.) of each of the data lanes to identify the data lane having the appended data. For example, the identifier analyzing circuitry 1206 can identify a first header byte or a first footer byte indicative of the data lane having the appended data. Specifically, the example identifier analyzing circuitry 1206 can determine whether the first header byte or the first footer byte includes a first value indicative of the data lane having the appended data.

At block 1906, the example weight decompression circuitry 1118 identifies a data lane having sliced data. For example, the lane decoding circuitry 1202 can determine which of the data lanes in the partitions include sliced data based on the identifiers associated with the data lanes. Specifically, the lane decoding circuitry 1202 can search for a second identifier indicative of the data lane having the largest uncompressed size of the all the data lanes in the partition, which is indicative of the data lane having the sliced data when compressed. In some examples, the identifier analyzing circuitry 1206 identifies the data lane having the sliced data based on a byte (e.g., the header byte, the footer byte, etc.) in each of the data lanes in the partition. Specifically, the example identifier analyzing circuitry 1206 can determine whether the byte includes a second value indicative of the data lane having the sliced data.

At block 1908, the example weight decompression circuitry 1118 identifies a slice size of the appended data. For example, the lane decoding circuitry 1202 can determine the slice size of the appended data based on a value stored in a predetermined position in the data lane having the first identifier. In some examples, the slice size determining circuitry 1208 determines the slice size based on data in a predetermined number of bytes adjacent to the header byte, adjacent to the footer byte, at a first or second end of the data lane, and/or at any other predetermined position in the data lane. In some examples, when the value in the data lane does not directly indicate the size of the appended data, the slice size determining circuitry 1208 performs a look-up in a table that correlates values, such as the value in the data lane, to sizes of appended data to determine the size of the appended data.

At block 1910, the example weight decompression circuitry 1118 identifies the appended data. For example, the lane decoding circuitry 1202 can identify the appended data based on the slice size and a predetermined location associated with the appended data. In some examples, the sliced data identifying circuitry 1210 (FIG. 12) identifies the appended data based on an amount of data corresponding to the slice size that is positioned at an end of the data lane or adjacent to the bytes indicating the slice size in the data lane having the appended data.

At block 1912, the example weight decompression circuitry 1118 moves the appended data back to the data lane having the largest uncompressed size in the partition. For example, the lane decoding circuitry 1202 moves the appended data to a predetermined part of the data lane having the largest uncompressed size in the partition. Specifically, the predetermined part of the data lane is based on where the weight compression circuitry 504 (FIG. 5) removed the appended data from the data lane in the example operation 1620, 1706 of FIGS. 16 and/or 17. In some examples, the data moving circuitry 1212 (FIG. 12) moves the appended data to an end of the data lane having the sliced data or to any other position predetermine area of the data lane.

At block 1914, the example weight decompression circuitry 1118 decompresses the data lanes in the partition. For example, the lane decompressing circuitry 1214 (FIG. 12) can decompress the data lanes in the partition in response to the appended data being moved to the data lane having the largest uncompressed size. In some examples, the lane decompressing circuitry 1214 transmits the decompressed data to the neural network circuitry 1102 (FIG. 11), which utilizes the data to perform an inference of detected and/or classified objects based on an image data input.

At block 1916, the example weight decompression circuitry 1118 determines whether there are more partitions to decompress. For example, the lane decoding circuitry 1202 can determine whether there are more partitions to decompress based on the number of accessed partitions and the number of partitions decompressed by the lane decompressing circuitry 1214. In some examples, the partition accessing circuitry 1204 (FIG. 12) determines there are more partitions to decompress in response to processing more partitions than the lane decompressing circuitry 1214, in which case the partition accessing circuitry 1204 provides a partition to be processed to the identifier analyzing circuitry 1206, and the example operations 1818 return to block 1904. Otherwise, when the partition accessing circuitry 1204 determines there are no more partitions to decompress, the operations 1818 end and control proceeds to block 1820 of FIG. 18.

FIG. 20 is a second flowchart representative of example machine readable instructions and/or example operations 2000 that may be executed and/or instantiated by processor circuitry to implement the weight decompression circuitry 1118 of FIGS. 11 and 12 to decompress neural network weights previously compressed in accordance with the example operations 1600, 1700 of FIGS. 16 and/or 17. The machine readable instructions and/or operations 2000 of FIG. 2000 begin at block 2002, at which the weight decompression circuitry 1118 (FIGS. 11 and 12) identifies a first data lane in a partition. For example, the lane decoding circuitry 1202 (FIG. 12) can identify the first data lane in the partition based on a first portion of data in the first data lane. In some examples, the identifier analyzing circuitry 1206 (FIG. 12) identifies the first data lane based on a header byte or a footer byte in the first data lane.

At block 2004, the weight decompression circuitry 1118 determines a size of a second portion of the first data. For example, the lane decoding circuitry 1202 can determine the size of the second portion of the first data based on a third portion of the first data. In some examples, the sliced data identifying circuitry 1210 (FIG. 12) determines the size of the second portion of the first data based on a value of the third portion of the first data. In some examples, the sliced data identifying circuitry 1210 utilizes a look-up table to correlate the third portion of the first data to the size of the second portion.

At block 2006, the weight decompression circuitry 1118 moves the second portion of the first data to a second data lane in the partition. For example, the lane decoding circuitry 1202 can cut the second portion of the first data to remove the second portion of the first data from the first data lane. Further the lane decoding circuitry 1202 can append the second portion of the first data to the second data lane. In some examples, the data moving circuitry 1212 (FIG. 12) moves the second portion of the first data to an end of the second data lane.

FIG. 21 is a block diagram of an example processor platform 2100 structured to execute and/or instantiate the machine readable instructions and/or operations of FIGS. 16 and/or 17 to implement the weight compression circuitry 504 of FIGS. 2, 4, and/or 5. The processor platform 2100 can be, for example, a server, a personal computer, a workstation, a self-learning machine (e.g., a neural network), a mobile device (e.g., a cell phone, a smart phone, a tablet such as an iPad™), a personal digital assistant (PDA), or any other type of computing device.

The processor platform 2100 of the illustrated example includes processor circuitry 2112. The processor circuitry 2112 of the illustrated example is hardware. For example, the processor circuitry 2112 can be implemented by one or more integrated circuits, logic circuits, FPGAs microprocessors, CPUs, GPUs, DSPs, and/or microcontrollers from any desired family or manufacturer. The processor circuitry 2112 may be implemented by one or more semiconductor based (e.g., silicon based) devices. In this example, the processor circuitry 2112 implements the pruning circuitry 602, the quantization circuitry 604, the variable length coding circuitry 606, the lane size computing circuitry 802, the lane identifying circuitry 804, the slice size computing circuitry 806, the data slicing circuitry 808, and the data appending circuitry 810.

The processor circuitry 2112 of the illustrated example includes a local memory 2113 (e.g., a cache, registers, etc.). The processor circuitry 2112 of the illustrated example is in communication with a main memory including a volatile memory 2114 and a non-volatile memory 2116 by a bus 2118. The volatile memory 2114 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2116 may be implemented by flash memory and/or any other desired type of memory device. Access to the main memory 2114, 2116 of the illustrated example is controlled by a memory controller 2117.

The processor platform 2100 of the illustrated example also includes interface circuitry 2120. The interface circuitry 2120 may be implemented by hardware in accordance with any type of interface standard, such as an Ethernet interface, a universal serial bus (USB) interface, a Bluetooth® interface, a near field communication (NFC) interface, a PCI interface, and/or a PCIe interface.

In the illustrated example, one or more input devices 2122 are connected to the interface circuitry 2120. The input device(s) 2122 permit(s) a user to enter data and/or commands into the processor circuitry 2112. The input device(s) 2122 can be implemented by, for example, an audio sensor, a microphone, a camera (still or video), a keyboard, a button, a mouse, a touchscreen, a track-pad, a trackball, an isopoint device, and/or a voice recognition system. In this example, the edge device 502 is in connection with the one or more input devices 2122.

One or more output devices 2124 are also connected to the interface circuitry 2120 of the illustrated example. The output devices 2124 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2120 of the illustrated example, thus, typically includes a graphics driver card, a graphics driver chip, and/or graphics processor circuitry such as a GPU. In this example, the one or more output devices 2124 implements the compressed weight transmitter 812. In this example, the one or more output devices 2124 are couple to the edge device 502.

The interface circuitry 2120 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2126. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 2100 of the illustrated example also includes one or more mass storage devices 2128 to store software and/or data. Examples of such mass storage devices 2128 include magnetic storage devices, optical storage devices, floppy disk drives, HDDs, CDs, Blu-ray disk drives, redundant array of independent disks (RAID) systems, solid state storage devices such as flash memory devices, and DVD drives.

The machine executable instructions 2132, which may be implemented by the machine readable instructions of FIGS. 16 and/or 17, may be stored in the mass storage device 2128, in the volatile memory 2114, in the non-volatile memory 2116, and/or on a removable non-transitory computer readable storage medium such as a CD or DVD.

FIG. 22 is a block diagram of an example processor platform 2200 structured to execute and/or instantiate the machine readable instructions and/or operations of FIGS. 18, 19, and/or 20 to implement the edge device 502 of FIGS. 2, 8, and 9. The processor platform 2200 can be, for example, a server, a personal computer, a workstation, a self-learning machine (e.g., a neural network), or any other type of computing device.

The processor platform 2200 of the illustrated example includes processor circuitry 2212. The processor circuitry 2212 of the illustrated example is hardware. For example, the processor circuitry 2212 can be implemented by one or more integrated circuits, logic circuits, FPGAs microprocessors, CPUs, GPUs, DSPs, and/or microcontrollers from any desired family or manufacturer. The processor circuitry 2212 may be implemented by one or more semiconductor based (e.g., silicon based) devices. In this example, the processor circuitry 2212 implements the neural network circuitry 1102, the data decoding circuitry 1108, the pixel activation circuitry 1110, the weight decompression circuitry 1118, the data encoding circuitry 1120, the lane decoding circuitry 1202, the partition accessing circuitry 1204, the identifier analyzing circuitry 1206, the slice size determining circuitry 1208, the sliced data identifying circuitry 1210, the data moving circuitry 1212, and the lane decompressing circuitry 1214.

The processor circuitry 2212 of the illustrated example includes a local memory 2213 (e.g., a cache, registers, etc.). The processor circuitry 2212 of the illustrated example is in communication with a main memory including a volatile memory 2214 and a non-volatile memory 2216 by a bus 2218. The volatile memory 2214 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2216 may be implemented by flash memory and/or any other desired type of memory device. Access to the main memory 2214, 2216 of the illustrated example is controlled by a memory controller 2217.

The processor platform 2200 of the illustrated example also includes interface circuitry 2220. The interface circuitry 2220 may be implemented by hardware in accordance with any type of interface standard, such as an Ethernet interface, a universal serial bus (USB) interface, a Bluetooth® interface, a near field communication (NFC) interface, a PCI interface, and/or a PCIe interface.

In the illustrated example, one or more input devices 2222 are connected to the interface circuitry 2220. The input device(s) 2222 permit(s) a user to enter data and/or commands into the processor circuitry 2212. The input device(s) 2222 can be implemented by, for example, an audio sensor, a microphone, a camera (still or video), a keyboard, a button, a mouse, a touchscreen, a track-pad, a trackball, an isopoint device, and/or a voice recognition system. In this example, the input device(s) 2222 is/are in connection with the weight compression circuitry 504.

One or more output devices 2224 are also connected to the interface circuitry 2220 of the illustrated example. The output devices 2224 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2220 of the illustrated example, thus, typically includes a graphics driver card, a graphics driver chip, and/or graphics processor circuitry such as a GPU.

The interface circuitry 2220 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2226. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 2200 of the illustrated example also includes one or more mass storage devices 2228 to store software and/or data. Examples of such mass storage devices 2228 include magnetic storage devices, optical storage devices, floppy disk drives, HDDs, CDs, Blu-ray disk drives, redundant array of independent disks (RAID) systems, solid state storage devices such as flash memory devices, and DVD drives.

The machine executable instructions 2232, which may be implemented by the machine readable instructions of FIGS. 16, 17, 18, 19, and/or 20, may be stored in the mass storage device 2228, in the volatile memory 2214, in the non-volatile memory 2216, and/or on a removable non-transitory computer readable storage medium such as a CD or DVD.

FIG. 23 is a block diagram of an example implementation of the processor circuitry 2112 of FIG. 21 and/or the processor circuitry 2212 of FIG. 22. In this example, the processor circuitry 2112 of FIG. 21 and/or the processor circuitry 2212 of FIG. 22 are implemented by a microprocessor 2300. For example, the microprocessor 2300 may implement multi-core hardware circuitry such as a CPU, a DSP, a GPU, an XPU, etc. Although it may include any number of example cores 2302 (e.g., 1 core), the microprocessor 2300 of this example is a multi-core semiconductor device including N cores. The cores 2302 of the microprocessor 2300 may operate independently or may cooperate to execute machine readable instructions. For example, machine code corresponding to a firmware program, an embedded software program, or a software program may be executed by one of the cores 2302 or may be executed by multiple ones of the cores 2302 at the same or different times. In some examples, the machine code corresponding to the firmware program, the embedded software program, or the software program is split into threads and executed in parallel by two or more of the cores 2302. The software program may correspond to a portion or all of the machine readable instructions and/or operations represented by the flowcharts of FIGS. 16, 17, 18, 19, and/or 20.

The cores 2302 may communicate by an example bus 2304. In some examples, the bus 2304 may implement a communication bus to effectuate communication associated with one(s) of the cores 2302. For example, the bus 2304 may implement at least one of an Inter-Integrated Circuit (I2C) bus, a Serial Peripheral Interface (SPI) bus, a PCI bus, or a PCIe bus. Additionally or alternatively, the bus 2304 may implement any other type of computing or electrical bus. The cores 2302 may obtain data, instructions, and/or signals from one or more external devices by example interface circuitry 2306. The cores 2302 may output data, instructions, and/or signals to the one or more external devices by the interface circuitry 2306. Although the cores 2302 of this example include example local memory 2320 (e.g., Level 1 (L1) cache that may be split into an L1 data cache and an L1 instruction cache), the microprocessor 2300 also includes example shared memory 2310 that may be shared by the cores (e.g., Level 2 (L2_cache)) for high-speed access to data and/or instructions. Data and/or instructions may be transferred (e.g., shared) by writing to and/or reading from the shared memory 2310. The local memory 2320 of each of the cores 2302 and the shared memory 2310 may be part of a hierarchy of storage devices including multiple levels of cache memory and the main memory (e.g., the main memory 2114, 2116 of FIG. 21, the main memory 2214, 2216 of FIG. 22). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 2302 may be referred to as a CPU, DSP, GPU, etc., or any other type of hardware circuitry. Each core 2302 includes control unit circuitry 2314, arithmetic and logic (AL) circuitry (sometimes referred to as an ALU) 2316, a plurality of registers 2318, the L1 cache 2320, and an example bus 2322. Other structures may be present. For example, each core 2302 may include vector unit circuitry, single instruction multiple data (SIMD) unit circuitry, load/store unit (LSU) circuitry, branch/jump unit circuitry, floating-point unit (FPU) circuitry, etc. The control unit circuitry 2314 includes semiconductor-based circuits structured to control (e.g., coordinate) data movement within the corresponding core 2302. The AL circuitry 2316 includes semiconductor-based circuits structured to perform one or more mathematic and/or logic operations on the data within the corresponding core 2302. The AL circuitry 2316 of some examples performs integer based operations. In other examples, the AL circuitry 2316 also performs floating point operations. In yet other examples, the AL circuitry 2316 may include first AL circuitry that performs integer based operations and second AL circuitry that performs floating point operations. In some examples, the AL circuitry 2316 may be referred to as an Arithmetic Logic Unit (ALU). The registers 2318 are semiconductor-based structures to store data and/or instructions such as results of one or more of the operations performed by the AL circuitry 2316 of the corresponding core 2302. For example, the registers 2318 may include vector register(s), SIMD register(s), general purpose register(s), flag register(s), segment register(s), machine specific register(s), instruction pointer register(s), control register(s), debug register(s), memory management register(s), machine check register(s), etc. The registers 2318 may be arranged in a bank as shown in FIG. 23. Alternatively, the registers 2318 may be organized in any other arrangement, format, or structure including distributed throughout the core 2302 to shorten access time. The bus 2320 may implement at least one of an I2C bus, a SPI bus, a PCI bus, or a PCIe bus

Each core 2302 and/or, more generally, the microprocessor 2300 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 2300 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 24 is a block diagram of another example implementation of the processor circuitry 2112 of FIG. 21 and/or the processor circuitry 2212 of FIG. 22. In this example, the processor circuitry 2112 of FIG. 21 and/or the processor circuitry 2212 of FIG. 22 are implemented by FPGA circuitry 2400. The FPGA circuitry 2400 can be used, for example, to perform operations that could otherwise be performed by the example microprocessor 2300 of FIG. 23 executing corresponding machine readable instructions. However, once configured, the FPGA circuitry 2400 instantiates the machine readable instructions in hardware and, thus, can often execute the operations faster than they could be performed by a general purpose microprocessor executing the corresponding software.

More specifically, in contrast to the microprocessor 2300 of FIG. 23 described above (which is a general purpose device that may be programmed to execute some or all of the machine readable instructions represented by the flowcharts of FIGS. 16, 17, 18, 19, and/or 20 but whose interconnections and logic circuitry are fixed once fabricated), the FPGA circuitry 2400 of the example of FIG. 24 includes interconnections and logic circuitry that may be configured and/or interconnected in different ways after fabrication to instantiate, for example, some or all of the machine readable instructions represented by the flowcharts of FIGS. 16, 17, 18, 19, and/or 20. In particular, the FPGA 2400 may be thought of as an array of logic gates, interconnections, and switches. The switches can be programmed to change how the logic gates are interconnected by the interconnections, effectively forming one or more dedicated logic circuits (unless and until the FPGA circuitry 2400 is reprogrammed). The configured logic circuits enable the logic gates to cooperate in different ways to perform different operations on data received by input circuitry. Those operations may correspond to some or all of the software represented by the flowcharts of FIGS. 16, 17, 18, 19, and/or 20. As such, the FPGA circuitry 2400 may be structured to effectively instantiate some or all of the machine readable instructions of the flowcharts of FIGS. 16, 17, 18, 19, and/or 20 as dedicated logic circuits to perform the operations corresponding to those software instructions in a dedicated manner analogous to an ASIC. Therefore, the FPGA circuitry 2400 may perform the operations corresponding to the some or all of the machine readable instructions of FIGS. 16, 17, 18, 19, and/or 20 faster than the general purpose microprocessor can execute the same.

In the example of FIG. 24, the FPGA circuitry 2400 is structured to be programmed (and/or reprogrammed one or more times) by an end user by a hardware description language (HDL) such as Verilog. The FPGA circuitry 2400 of FIG. 24, includes example input/output (I/O) circuitry 2402 to obtain and/or output data to/from example configuration circuitry 2404 and/or external hardware (e.g., external hardware circuitry) 2406. For example, the configuration circuitry 2404 may implement interface circuitry that may obtain machine readable instructions to configure the FPGA circuitry 2400, or portion(s) thereof. In some such examples, the configuration circuitry 2404 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 2406 may implement the microprocessor 2300 of FIG. 23. The FPGA circuitry 2400 also includes an array of example logic gate circuitry 2408, a plurality of example configurable interconnections 2410, and example storage circuitry 2412. The logic gate circuitry 2408 and interconnections 2410 are configurable to instantiate one or more operations that may correspond to at least some of the machine readable instructions of FIGS. 16, 17, 18, 19, and/or 20 and/or other desired operations. The logic gate circuitry 2408 shown in FIG. 24 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2408 to enable configuration of the electrical structures and/or the logic gates to form circuits to perform desired operations. The logic gate circuitry 2408 may include other electrical structures such as look-up tables (LUTs), registers (e.g., flip-flops or latches), multiplexers, etc.

The interconnections 2410 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2408 to program desired logic circuits.

The storage circuitry 2412 of the illustrated example is structured to store result(s) of the one or more of the operations performed by corresponding logic gates. The storage circuitry 2412 may be implemented by registers or the like. In the illustrated example, the storage circuitry 2412 is distributed amongst the logic gate circuitry 2408 to facilitate access and increase execution speed.

The example FPGA circuitry 2400 of FIG. 24 also includes example Dedicated Operations Circuitry 2414. In this example, the Dedicated Operations Circuitry 2414 includes special purpose circuitry 2416 that may be invoked to implement commonly used functions to avoid the need to program those functions in the field. Examples of such special purpose circuitry 2416 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2400 may also include example general purpose programmable circuitry 2418 such as an example CPU 2420 and/or an example DSP 2422. Other general purpose programmable circuitry 2418 may additionally or alternatively be present such as a GPU, an XPU, etc., that can be programmed to perform other operations.

Although FIGS. 23 and 24 illustrate two example implementations of the processor circuitry 2112 of FIG. 21 and/or the processor circuitry 2212 of FIG. 22, many other approaches are contemplated. For example, as mentioned above, modern FPGA circuitry may include an on-board CPU, such as one or more of the example CPU 2420 of FIG. 24. Therefore, the processor circuitry 2112 of FIG. 21 and/or the processor circuitry 2212 of FIG. 22 may additionally be implemented by combining the example microprocessor 2300 of FIG. 23 and the example FPGA circuitry 2400 of FIG. 24. In some such hybrid examples, a first portion of the machine readable instructions represented by the flowcharts of FIGS. 16, 17, 18, 19, and/or 20 may be executed by one or more of the cores 2302 of FIG. 23 and a second portion of the machine readable instructions represented by the flowcharts of FIGS. 16, 17, 18, 19, and/or 20 may be executed by the FPGA circuitry 2400 of FIG. 24.

In some examples, the processor circuitry 2112 of FIG. 21 and/or the processor circuitry 2212 of FIG. 22 may be in one or more packages. For example, the processor circuitry 2300 of FIG. 23 and/or the FPGA circuitry 2400 of FIG. 24 may be in one or more packages. In some examples, an XPU may be implemented by the processor circuitry 2112 of FIG. 21 and/or the processor circuitry 2212 of FIG. 22, which may be in one or more packages. For example, the XPU may include a CPU in one package, a DSP in another package, a GPU in yet another package, and an FPGA in still yet another package.

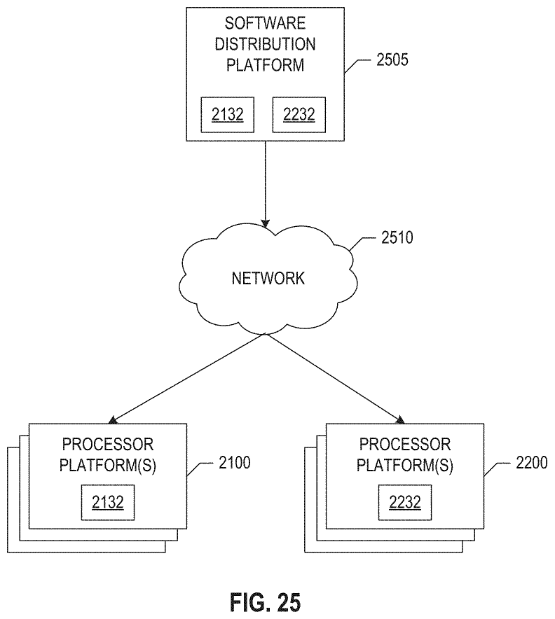

A block diagram illustrating an example software distribution platform 2505 to distribute software such as the example machine readable instructions 2132 of FIG. 21 and/or the example machine readable instructions 2232 of FIG. 22 to hardware devices owned and/or operated by third parties is illustrated in FIG. 25. The example software distribution platform 2505 may be implemented by any computer server, data facility, cloud service, etc., capable of storing and transmitting software to other computing devices. The third parties may be customers of the entity owning and/or operating the software distribution platform 2505. For example, the entity that owns and/or operates the software distribution platform 2505 may be a developer, a seller, and/or a licensor of software such as the example machine readable instructions 2132 of FIG. 21 and/or the example machine readable instructions 2232 of FIG. 22. The third parties may be consumers, users, retailers, OEMs, etc., who purchase and/or license the software for use and/or re-sale and/or sub-licensing. In the illustrated example, the software distribution platform 2505 includes one or more servers and one or more storage devices. The storage devices store the machine readable instructions 2132, 2232, which may correspond to the example machine readable instructions 1600, 1700, 1800, 1900, 2000 of FIGS. 16-20, as described above. The one or more servers of the example software distribution platform 2505 are in communication with a network 2510, which may correspond to any one or more of the Internet and/or any of the example networks 2126, 2226 described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 2132 of FIG. 21 and/or the example machine readable instructions 2232 of FIG. 22 from the software distribution platform 2005. For example, the software, which may correspond to the example machine readable instructions 2132 of FIG. 21 and/or the example machine readable instructions 2232 of FIG. 22, may be downloaded to the example processor platform 2100 and/or the example processor platform 2200, which are to execute the machine readable instructions 2132 and the machine readable instructions 2232, respectively, to implement the weight compression circuitry 504 and the edge device 502, respectively. In some example, one or more servers of the software distribution platform 2505 periodically offer, transmit, and/or force updates to the software (e.g., the example machine readable instructions 2132 of FIG. 21 and/or the example machine readable instructions 2232 of FIG. 22) to ensure improvements, patches, updates, etc., are distributed and applied to the software at the end user devices.

From the foregoing, it will be appreciated that example systems, methods, apparatus, and articles of manufacture have been disclosed that enable high throughput compression of neural network weights. The disclosed systems, methods, apparatus, and articles of manufacture improve the efficiency of using a computing device by reducing an amount of space used to store neural network weights. Additionally, the disclosed systems, methods, apparatus, and articles of manufacture enable compression and/or decompression of multiple partitions in parallel. The disclosed systems, methods, apparatus, and articles of manufacture are accordingly directed to one or more improvement(s) in the operation of a machine such as a computer or other electronic and/or mechanical device.

Example methods, apparatus, systems, and articles of manufacture for high throughput compression of neural network weights are disclosed herein. Further examples and combinations thereof include the following:

Example 1 includes an apparatus comprising at least one memory, instructions in the apparatus, and processor circuitry to execute the instructions to determine sizes of data lanes in a partition of neural network weights, determine a slice size based on a size difference between a first data lane and a second data lane of the data lanes in the partition, the first data lane including first data, the second data lane including second data, the second data of a smaller size than the first data, cut a portion of the first data from the first data lane based on the slice size, and append the portion of the first data to the second data lane.

Example 2 includes the apparatus of example 1, wherein the processor circuitry is to execute the instructions to record a value corresponding to the slice size in the second data lane.

Example 3 includes the apparatus of example 2, wherein the value corresponding to the slice size is indicative of a size of the portion of the first data in the second data lane.

Example 4 includes the apparatus of example 1, wherein the slice size is within 50 bytes of half of the size difference between the first data lane and the second data lane.

Example 5 includes the apparatus of example 1, wherein the portion of the first data is positioned after the second data in the second data lane.

Example 6 includes the apparatus of example 1, wherein the processor circuitry is to execute the instructions to assign a first identifier to the first data lane, and assign a second identifier to the second data lane, the second identifier different from the first identifier.

Example 7 includes the apparatus of example 6, wherein the first identifier is a first header byte recorded in the first data lane and the second identifier is a second header byte recorded in the second data lane.

Example 8 includes the apparatus of example 6, wherein the processor circuitry is to execute the instructions to assign a third identifier to a third data lane of the data lanes in the partition, the third data lane including third data, the third data of a smaller size than the first data and a larger size than the second data.

Example 9 includes the apparatus of example 1, wherein the portion of the first data is cut from an end of the first data lane.

Example 10 includes the apparatus of example 1, wherein the first data lane is positioned adjacent the second data lane in the partition.

Example 11 includes a non-transitory machine executable medium comprising instructions which, when executed, cause one or more processors to at least determine sizes of data lanes in a partition of neural network weights, determine a slice size based on a size difference between a first data lane and a second data lane of the data lanes in the partition, the first data lane including first data, the second data lane including second data, the second data of smaller size than the first data, cut a portion of the first data from the first data lane based on the slice size, and append the portion of the first data to the second data lane.

Example 12 includes the non-transitory machine executable medium of example 11, wherein the instructions, when executed, cause the one or more processors to write a first identifier at a first end of the first data lane, the first identifier indicative of data to be removed from the first data lane, and write a second identifier at a second end of the second data lane, the second identifier indicative of data to be added to the second data lane.

Example 13 includes the non-transitory machine executable medium of example 11, wherein the instructions, when executed, cause the one or more processors to write a value corresponding to the slice size in the second data lane.

Example 14 includes the non-transitory machine executable medium of example 11, wherein the instructions, when executed, cause the one or more processors to cut the portion of the first data from a first end of the first data lane.

Example 15 includes the non-transitory machine executable medium of example 14, wherein the instructions, when executed, cause the one or more processors to append the portion of the first data to a second end of the second data lane.

Example 16 includes the non-transitory machine executable medium of example 11, wherein in response to appending the portion of the first data to the second data lane, the first data lane includes a first size and the second data lane includes a second size within 200 bytes of the first size.

Example 17 includes an apparatus comprising first means for determining sizes of data lanes, second means for determining a slice size based on a size difference between a first data lane and a second data lane of the data lanes, the first data lane including first data, the second data lane including second data, the second data of a smaller size than the first data, means for cutting a portion of the first data from the first data lane based on the slice size, and means for appending the portion of the first data to the second data lane.

Example 18 includes the apparatus of example 17, wherein the first data lane and the second data lane are in a partition.

Example 19 includes the apparatus of example 18, further including means for identifying to identify the first data lane in response to determining the first data has a smallest size in the partition, and identify the second data lane in response to determining the second data has a largest size in the partition.

Example 20 includes the apparatus of example 17, wherein the first data and the second data correspond to neural network weights.

Example 21 includes the apparatus of example 17, further including means for assigning to assign a first identifier to a first end of the first data lane, the first identifier indicative of data to be removed from the first data lane, and assign a second identifier to a second end of the second data lane, the second identifier indicative of data to be appended to the second data lane.

Example 22 includes the apparatus of example 17, further including means for recording the slice size or a value corresponding to the slice size in the second data lane.

Example 23 includes an apparatus comprising at least one memory, instructions in the apparatus, and processor circuitry to execute the instructions to identify a first data lane in a partition based on a first portion of first data in the first data lane, determine a size of a second portion of the first data based on a third portion of the first data, and move the second portion of the first data to a second data lane in the partition.

Example 24 includes the apparatus of example 23, wherein the first portion of the first data is positioned at an end of the first data lane.

Example 25 includes the apparatus of example 23, wherein the processor circuitry is to execute the instructions to locate the second portion of the first data at an end of the first data lane based on the size.

Example 26 includes the apparatus of example 23, wherein the processor circuitry is to execute the instructions to move the second portion of the first data to an end of the second data lane.

Example 27 includes the apparatus of example 23, wherein the processor circuitry is to execute the instructions to identify the second data lane based on a portion of second data in the second data lane.

Example 28 includes the apparatus of example 23, wherein a size difference between the first data lane and the second data lane increases in response to moving the second portion of the first data to the second data lane.

Example 29 includes the apparatus of example 23, wherein the processor circuitry is to execute the instructions to determine the size of the second portion of the first data is a first size in response to the third portion of the first data including a first value, and determine the size of the second portion of the first data is a second size in response to the third portion of the first data including a second value.

Example 30 includes a non-transitory machine executable medium comprising instructions which, when executed, cause one or more processors to at least identify a first data lane in a partition based on a first portion of first data in the first data lane, determine a size of a second portion of the first data based on a third portion of the first data, and move the second portion of the first data to a second data lane in the partition.

Example 31 includes the non-transitory machine executable medium of example 30, wherein the first portion of the first data is positioned at an end of the first data lane.

Example 32 includes the non-transitory machine executable medium of example 30, wherein the instructions, when executed, cause the one or more processors to locate the second portion of the first data at an end of the first data lane based on the size.

Example 33 includes the non-transitory machine executable medium of example 30, wherein the instructions, when executed, cause the one or more processors to move the second portion of the first data to an end of the second data lane.

Example 34 includes the non-transitory machine executable medium of example 30, wherein the instructions, when executed, cause the one or more processors to identify the second data lane based on a portion of second data in the second data lane.

Example 35 includes the non-transitory machine executable medium of example 30, wherein a size difference between the first data lane and the second data lane increases in response to moving the second portion of the first data to the second data lane.

Example 36 includes the apparatus of example 23, wherein the instructions, when executed, cause the one or more processors to determine the size of the second portion of the first data is a first size in response to the third portion of the first data including a first value, and determine the size of the second portion of the first data is a second size in response to the third portion of the first data including a second value.

Example 37 includes an apparatus comprising means for identifying a first data lane in a partition based on a first portion of first data in the first data lane, means for determining a size of a second portion of the first data based on a third portion of the first data, and means for moving the second portion of the first data to a second data lane in the partition.

Example 38 includes the apparatus of example 37, wherein the first portion of the first data is positioned at an end of the first data lane.

Example 39 includes the apparatus of example 37, further including means for locating the second portion of the first data at an end of the first data lane based on the size.

Example 40 includes the apparatus of example 37, wherein the means for moving is to move the second portion of the first data to an end of the second data lane.

Example 41 includes the apparatus of example 37, wherein the means for identifying is to identify the second data lane based on a portion of second data in the second data lane.

Example 42 includes the apparatus of example 37, wherein the means for moving is to increase a size difference between the first data lane and the second data lane in response to moving the second portion of the first data to the second data lane.

Example 43 includes the apparatus of example 37, wherein the means for determining is to determine the size of the second portion of the first data is a first size in response to the third portion of the first data including a first value, and determine the size of the second portion of the first data is a second size in response to the third portion of the first data including a second value.

Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

The following claims are hereby incorporated into this Detailed Description by this reference, with each claim standing on its own as a separate embodiment of the present disclosure.

1. An apparatus comprising:
at least one memory;
instructions in the apparatus; and
processor circuitry to execute the instructions to:
determine sizes of data lanes in a partition of neural network weights;
determine a slice size based on a size difference between a first data lane and a second data lane of the data lanes in the partition, the first data lane including first data, the second data lane including second data, the second data of a smaller size than the first data;
cut a portion of the first data from the first data lane based on the slice size; and
append the portion of the first data to the second data lane.

2. The apparatus of claim 1, wherein the processor circuitry is to execute the instructions to record a value corresponding to the slice size in the second data lane.

3. The apparatus of claim 2, wherein the value corresponding to the slice size is indicative of a size of the portion of the first data in the second data lane.

4. The apparatus of claim 1, wherein the slice size is within 50 bytes of half of the size difference between the first data lane and the second data lane.

5. The apparatus of claim 1, wherein the portion of the first data is positioned after the second data in the second data lane.

6. The apparatus of claim 1, wherein the processor circuitry is to execute the instructions to:
assign a first identifier to the first data lane; and
assign a second identifier to the second data lane, the second identifier different from the first identifier.

7. The apparatus of claim 6, wherein the first identifier is a first header byte recorded in the first data lane and the second identifier is a second header byte recorded in the second data lane.

8. The apparatus of claim 6, wherein the processor circuitry is to execute the instructions to assign a third identifier to a third data lane of the data lanes in the partition, the third data lane including third data, the third data of a smaller size than the first data and a larger size than the second data.

9. The apparatus of claim 1, wherein the portion of the first data is cut from an end of the first data lane.

10. The apparatus of claim 1, wherein the first data lane is positioned adjacent the second data lane in the partition.

11. A non-transitory machine executable medium comprising instructions which, when executed, cause one or more processors to at least:
determine sizes of data lanes in a partition of neural network weights;
determine a slice size based on a size difference between a first data lane and a second data lane of the data lanes in the partition, the first data lane including first data, the second data lane including second data, the second data of smaller size than the first data;
cut a portion of the first data from the first data lane based on the slice size; and
append the portion of the first data to the second data lane.

12. The non-transitory machine executable medium of claim 11, wherein the instructions, when executed, cause the one or more processors to:
write a first identifier at a first end of the first data lane, the first identifier indicative of data to be removed from the first data lane; and
write a second identifier at a second end of the second data lane, the second identifier indicative of data to be added to the second data lane.

13. The non-transitory machine executable medium of claim 11, wherein the instructions, when executed, cause the one or more processors to write a value corresponding to the slice size in the second data lane.

14. The non-transitory machine executable medium of claim 11, wherein the instructions, when executed, cause the one or more processors to cut the portion of the first data from a first end of the first data lane.

15. The non-transitory machine executable medium of claim 14, wherein the instructions, when executed, cause the one or more processors to append the portion of the first data to a second end of the second data lane.

16. The non-transitory machine executable medium of claim 11, wherein in response to appending the portion of the first data to the second data lane, the first data lane includes a first size and the second data lane includes a second size within 200 bytes of the first size.

17. An apparatus comprising:
first means for determining sizes of data lanes;
second means for determining a slice size based on a size difference between a first data lane and a second data lane of the data lanes, the first data lane including first data, the second data lane including second data, the second data of a smaller size than the first data;
means for cutting a portion of the first data from the first data lane based on the slice size; and
means for appending the portion of the first data to the second data lane.

18. The apparatus of claim 17, wherein the first data lane and the second data lane are in a partition.

19. The apparatus of claim 18, further including means for identifying to:
identify the first data lane in response to determining the first data has a smallest size in the partition; and
identify the second data lane in response to determining the second data has a largest size in the partition.

20. The apparatus of claim 17, wherein the first data and the second data correspond to neural network weights.

21. The apparatus of claim 17, further including means for assigning to:
assign a first identifier to a first end of the first data lane, the first identifier indicative of data to be removed from the first data lane; and
assign a second identifier to a second end of the second data lane, the second identifier indicative of data to be appended to the second data lane.

22. The apparatus of claim 17, further including means for recording the slice size or a value corresponding to the slice size in the second data lane.

23.-43. (canceled)
